(19) United States
(12) Patent Application Publication
(10) Pub. No.: US 2007/0018255 A1
(43) Pub. Date: Jan. 25, 2007

(54) Semiconductor device and method for fabricating the same

(75) Inventor: Kazuo Kawamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/511,472

(22) Filed: Aug. 29, 2006

Related U.S. Application Data
(63) Continuation of application No. PCT/JP05/08536, filed on May 10, 2005.

(30) Foreign Application Priority Data
May 17, 2004 (JP) 2004-146763
Oct. 7, 2004 (JP) 2004-294855

(51) Int. Cl. H01L 29/76

(52) U.S. Cl. 257/382

(57) ABSTRACT

The method for fabricating a semiconductor device according to the present invention comprises the step of forming a Ni film 66 on source/drain diffused layers 64, the step of performing a first thermal processing to react a lower part of the Ni film 66 and an upper part of the source/drain diffused layers 64 with each other to form Ni₂Si films 70b on the source/drain diffused layers 64, the step of etching off selectively a part of the Ni film 66, which has not reacted, and the step of performing a second thermal processing to further react the Ni₂Si film 70b and an upper part of the source/drain diffused layers 64 with each other.

### CROSS REFERENCE TO RELATED APPLICATIONS

This application is a Continuation of International Application No. PCT/JP2005/008536, with an international filing date of May 10, 2005, which designated the United States of America.

### TECHNICAL FIELD

The present invention relates to a semiconductor device and a method for fabricating the same, more specifically, a semiconductor device and a method for fabricating the same in which silicidation with nickel is performed.

### BACKGROUND ART

As a technique of making the gate electrode and the source/drain diffused layers low resistive, the so-called salicide (self-aligned silicide) process that metal silicide film is formed on the surfaces of the gate electrode and the source/drain diffused layers by self-alignment is known. As the metal material reacted with silicon in the salicide process, cobalt (Co) is widely used (see, e.g., Patent Reference 1).

On the other hand, as the semiconductor device is increasingly integrated, the structure of the semiconductor device is rapidly increasingly fined. Specifically, the junction depth of the source/drain diffused layer is as small as below 80 nm excluding 80 nm. The film thickness of the metal silicide film formed on the source/drain diffused layer is as small as below 20 nm excluding 20 nm. The gate length is as small as below 50 nm excluding 50 nm.

While the structure of the semiconductor device is being increasingly fined, the phenomenon that the scatter of the resistance of the gate electrode abruptly increases when Co is used to form CoSi₂ film on the gate electrode is observed in fabricating a semiconductor device having the gate electrode with a gate length below 40 nm including 40 nm.

In contrast to such CoSi₂, nickel silicide is much noted because of the advantage that the resistance of the gate electrode is stable even when the gate length is below 40 nm excluding 40 nm.

The following references disclose the background art of the present invention.

[Patent Reference 1]

Japanese Patent Application Unexamined Publication No. Hei 9-251967 (1997)

[Patent Reference 2]

Specification of U.S. Pat. No. 6,621,131

### DISCLOSURE OF THE INVENTION

### Problems to be Solved by the Invention

However, when Ni film is simply used for the silicidation, the roughness in the interface between the silicon layer and the silicide film becomes large, and often the scatter of the sheet resistance of the source/drain diffused layer is increased, and the junction leak current is increased.

An object of the present invention is to provide a semiconductor device which can suppress the scatter of the sheet resistance of the source/drain diffused layers and the junction leak current, and a method for fabricating the same.

### MEANS FOR SOLVING THE PROBLEMS

According to one aspect of the present invention, there is provided a semiconductor device comprising: a gate electrode formed on a semiconductor substrate; a source/drain diffused layer formed in the semiconductor substrate on both sides of the gate electrode; and a silicide film formed on the source/drain diffused layer, the silicide film being formed of nickel monosilicide, and a film thickness of the silicide film being below 20 nm including 20 nm.

According to another aspect of the present invention, there is provided a semiconductor device comprising: a gate electrode formed on a semiconductor substrate; a source/drain diffused layer formed in the semiconductor substrate on both sides of the gate electrode; an Si₁₋ₓGeₓ film which is buried in the source/drain diffused layer and whose composition ratio x is 0<x<1; and a silicide film formed on the Si₁₋ₓGeₓ film, the silicide film being formed of NiSi₁₋ₓGeₓ whose composition ratio x is 0<x<1, and a film thickness of the silicide film being below 20 nm including 20 nm.

According to further another aspect of the present invention, there is provided a semiconductor device comprising: a gate electrode formed on a semiconductor substrate; a source/drain diffused layer formed in the semiconductor substrate on both sides of the gate electrode, an Si_{1-x-y}GeₓC_{y} film which is buried in the source/drain diffused layer and whose composition ratios x, y satisfy 0<x<1, 0<y<0.01 and 1−x−y>0; and a silicide film formed on the Si_{1-x-y}GeₓC_{y} film, the silicide film being formed of NiSi_{1-x-y}GeₓC_{y} whose composition ratios x, y satisfy 0<x<1, 0<y<0.01 and 1−x−y>0, and a film thickness of the silicide film being below 20 nm including 20 nm.

According to further another aspect of the present invention, there is provided a method for fabricating a semiconductor device comprising the steps of: forming a gate electrode on a semiconductor substrate; forming a source/drain diffused layer in the semiconductor substrate on both sides of the gate electrode; forming a nickel film on the source/drain diffused layer; performing a first thermal processing to react a lower part of the nickel film and an upper part of the source/drain diffused layer with each other to form a nickel silicide film on the source/drain diffused layer; etching off selectively a part of the nickel film, which has not reacted; and performing a second thermal processing to further react the nickel silicide film and an upper part of the source/drain diffused layer with each other.

According to further another aspect of the present invention, there is provided a method for fabricating a semiconductor device comprising the steps of: forming a gate electrode on a semiconductor substrate; forming a source/drain diffused layer in the semiconductor substrate on both sides of the gate electrode; burying Si₁₋ₓGeₓ film whose composition ratio x is 0<x<1 in the source/drain diffused layer; forming a nickel film on the Si₁₋ₓGeₓ film; performing a first thermal processing to react a lower part of the nickel film and an upper part of the Si₁₋ₓGeₓ film to form a nickel silicide film on the Si₁₋ₓGeₓ film; etching off selectively a part of the nickel film, which has not reacted; and performing a second thermal processing to further react the nickel silicide film and an upper part of the Si₁₋ₓGeₓ film with each other.

According to further another aspect of the present invention, there is provided a method for fabricating a semiconductor device comprising the steps of: forming a gate electrode on a semiconductor substrate; forming a source/drain diffused layer in the semiconductor substrate on both sides of the gate electrode; burying an Si_{1-x-y}GeₓC_{y} film whose composition ratios x, y satisfy 0<x<1, 0<y<0.01 and 1−x−y>0 in the source/drain diffused layer; forming a nickel film on the Si_{1-x-y}GeₓC_{y} film; performing a first thermal processing to react a lower part of the nickel film and an upper part of the Si_{1-x-y}GeₓC_{y} film with each other to form a nickel silicide film on the Si_{1-x-y}GeₓC_{y} film; etching off selectively a part of the nickel film, which has not reacted; and performing a second thermal processing to further react the nickel silicide film and an upper part of the Si_{1-x-y}GeₓC_{y} film with each other.

### EFFECTS OF THE INVENTION

According to the present invention, by the first thermal processing, a lower part of a relatively thick nickel film and an upper part of a silicon substrate are reacted with each other, whereby by the first thermal processing, an Ni₂Si film can be formed while the formation of NiSi₂ crystals is being suppressed. Then, in the present invention, after the part of the nickel film, which has not reacted with Si, is selectively etched off, by the second thermal processing, the Ni₂Si film and an upper part of the silicon substrate are reacted with each other to form an NiSi film, whereby the NiSi film is prevented from being formed too thick. Furthermore, according to the present invention, the conditions for the first and the second thermal processing are suitably set, whereby the film thickness of the NiSi film can be controlled. Thus, according to the present invention, the NiSi film of good quality and low resistance can be formed in a required film thickness on the silicon substrate while the formation of NiSi₂ film of high resistance is being suppressed, and the roughness in the interface between the silicon substrate and the NiSi film can be made small. Thus, when the surface of the gate electrode and the surface of the source/drain diffused layer are silicided, the scatter of the sheet resistance can be suppressed. The junction leak current can be suppressed.

According to the present invention, by the first thermal processing, a lower part of a relatively thick nickel film and an upper part of the Si₁₋ₓGeₓ film are reacted with each other, whereby an Ni₂Si₁₋ₓGeₓ film can be formed while the formation of Ni(Si₁₋ₓGeₓ)₂ crystals is being suppressed. Then, in the present invention, after the part of the nickel film, which has not reacted with Si₁₋ₓGeₓ, is selectively etched off, by the second thermal processing, the Ni₂Si₁₋ₓGeₓ film and an upper part of the Si₁₋ₓGeₓ film are reacted with each other to form an NiSi₁₋ₓGeₓ film, whereby the NiSi₁₋ₓGeₓ film is prevented from being formed too thick. Furthermore, according to the present invention, the conditions for the first and the second thermal processing are suitably set, whereby the film thickness of the NiSi₁₋ₓGeₓ film can be controlled. Thus, according to the present invention, the NiSi₁₋ₓGeₓ film of low resistance and good quality can be formed in a required film thickness on the Si₁₋ₓGeₓ film while the formation of Ni(Si₁₋ₓGeₓ)₂ film of high resistance is being suppressed. The roughness in the interface between the Si₁₋ₓGeₓ film and the NiSi₁₋ₓGeₓ film can be made small. Thus, when the surface of the gate electrode having the Si₁₋ₓGeₓ film on the top and the surface of the Si₁₋ₓGeₓ film buried in the source/drain diffused layer are silicided, the scatter of the sheet resistance can be suppressed. The junction leak current can be suppressed. Besides, according to the present invention, compressive strain is exerted to the channel layer of the PMOS transistor by the Si₁₋ₓGeₓ film buried in the source/drain diffused layer of the PMOS transistor, whereby the operation speed of the PMOS transistor can be improved.

According to the present embodiment, by the first thermal processing, a lower part of a relatively thick nickel film and an upper part of the Si_{1-x-y}GeₓC_{y} film are reacted with each other, whereby by the first thermal processing, an Ni₂Si_{1-x-y}GeₓC_{y} film can be formed while the formation of Ni(Si_{1-x-y}GeₓC_{y})₂ crystals is being suppressed. Then, in the present invention, after the part of the nickel film, which has not reacted with Si_{1-x-y}GeₓC_{y}, is selectively etched off, by the second thermal processing, the Ni₂Si_{1-x-y}GeₓC_{y} film and an upper part of the Si_{1-x-y}GeₓC_{y} film are reacted with each other to form an NiSi_{1-x-y}GeₓC_{y} film, whereby the NiSi_{1-x-y}GeₓC_{y} film is prevented from being formed too thick. Furthermore, the conditions for the first and the second thermal processing are suitably set, whereby the film thickness of the NiSi_{1-x-y}GeₓC_{y} film can be controlled. Thus, according to the present invention, the NiSi_{1-x-y}GeₓC_{y} film of low resistance and good quality can be formed in a required film thickness on the Si_{1-x-y}GeₓC_{y} film while the formation of Ni(Si_{1-x-y}GeₓC_{y})₂ film of high resistance is being suppressed. The roughness in the interface between the Si_{1-x-y}GeₓC_{y} film and the NiSi_{1-x-y}GeₓC_{y} film can be made small. Thus, when the surface of the gate electrode having the Si_{1-x-y}GeₓC_{y} film on the top and the surface of the Si_{1-x-y}GeₓC_{y} film buried in the source/drain diffused layer are silicided, the scatter of the sheet resistance can be suppressed. The junction leak current can be suppressed. Furthermore, according to the present invention, tensile strain is exerted to the channel layer of the NMOS transistor by the Si_{1-x-y}GeₓC_{y} film buried in the source/drain diffused layer of the NMOS transistor, whereby the operation speed of the NMOS transistor can be improved.

### BRIEF DESCRIPTION OF DRAWINGS

FIGS. 1A-1E are diagrammatic sectional views illustrating a reaction model of the silicidation process of the nickel silicide (Part 1).

FIGS. 2A-2D are diagrammatic sectional views illustrating a reaction model of the silicidation process of the nickel silicide (Part 2).

FIG. 3 is a diagrammatic sectional view of the MOS transistor subjected to the salicide process using a relatively thin Ni film, which illustrates a structure thereof.

FIG. 4 is a graph of the result of the experiment of measuring sheet resistances of the source/drain diffused layers silicided using Ni film of different thicknesses.

FIGS. 5A-5D are diagrammatic sectional views explaining the principle of the present invention.

FIG. 6 is a graph schematically showing the relationship between the Gibbs free energy of the system formed of a silicon substrate and a nickel silicide film, and the film thickness of the Ni film.

FIG. 7 is a sectional view of the semiconductor device according to a first embodiment of the present invention, which illustrates a structure thereof.

FIGS. 8A-8C are sectional views of the semiconductor device according to the first embodiment of the present invention in the steps of the method for fabricating the same, which illustrate the method (Part 1).

FIGS. 9A-9C are sectional views of the semiconductor device according to the first embodiment of the present invention in the steps of the method for fabricating the same, which illustrate the method (Part 2).

FIGS. 10A-10C are sectional views of the semiconductor device according to the first embodiment of the present invention in the steps of the method for fabricating the same, which illustrate the method (Part 3).

FIGS. 11A-11C are sectional views of the semiconductor device according to the first embodiment of the present invention in the steps of the method for fabricating the same, which illustrate the method (Part 4).

FIGS. 12A-12C are sectional views of the semiconductor device according to the first embodiment of the present invention in the steps of the method for fabricating the same, which illustrate the method (Part 5).

FIGS. 13A-13C are sectional views of the semiconductor device according to the first embodiment of the present invention in the steps of the method for fabricating the same, which illustrate the method (Part 6).

FIGS. 14A-14C are sectional views of the semiconductor device according to the first embodiment of the present invention in the steps of the method for fabricating the same, which illustrate the method (Part 7).

FIGS. 15A-15C are sectional views of the semiconductor device according to the first embodiment of the present invention in the steps of the method for fabricating the same, which illustrate the method (Part 8).

FIGS. 16A-16C are sectional views of the semiconductor device according to the first embodiment of the present invention in the steps of the method for fabricating the same, which illustrate the method (Part 9).

FIGS. 17A-17C are sectional views of the semiconductor device according to the first embodiment of the present invention in the steps of the method for fabricating the same, which illustrate the method (Part 10).

FIGS. 18A-18C are sectional views of the semiconductor device according to the first embodiment of the present invention in the steps of the method for fabricating the same, which illustrate the method (Part 11).

FIGS. 19A-19D are transmission electron microscopic pictures showing the result of evaluating the method for fabricating the semiconductor device according to the first embodiment of the present invention.

FIG. 20 is a sectional view of the semiconductor device used in evaluating the method for fabricating the semiconductor device according to the first embodiment of the present invention.

FIG. 21 is a graph showing the result of evaluating the method for fabricating the semiconductor device according to the first embodiment of the present invention (Part 1).

FIG. 22 is a graph showing the result of evaluating the method for fabricating the semiconductor device according to the first embodiment of the present invention (Part 2).

FIGS. 23A-23C are sectional views of the semiconductor device according to a second embodiment of the present invention in the steps of the method for fabricating the same, which illustrate the method.

FIG. 24 is a sectional view of the semiconductor device according to a third embodiment of the present invention, which illustrates a structure thereof.

FIGS. 25A-25B are sectional views of the semiconductor device according to the third embodiment of the present invention in the steps of the method for fabricating the same, which illustrate the method (Part 1).

FIGS. 26A-26B are sectional views of the semiconductor device according to the third embodiment of the present invention in the steps of the method for fabricating the same, which illustrate the method (Part 2).

FIGS. 27A-27B are sectional views of the semiconductor device according to the third embodiment of the present invention in the steps of the method for fabricating the same, which illustrate the method (Part 3).

FIGS. 28A-28B are sectional views of the semiconductor device according to the third embodiment of the present invention in the steps of the method for fabricating the same, which illustrate the method (Part 4).

FIGS. 29A-29B are sectional views of the semiconductor device according to the third embodiment of the present invention in the steps of the method for fabricating the same, which illustrate the method (Part 5).

FIG. 30 is a sectional view of the semiconductor device according to a fourth embodiment of the present invention, which illustrates a structure thereof.

FIGS. 31A-31B are sectional views of the semiconductor device according to the fourth embodiment of the present invention in the steps of the method for fabricating the same, which illustrate the method (Part 1).

FIGS. 32A-32B are sectional views of the semiconductor device according to the fourth embodiment of the present invention in the steps of the method for fabricating the same, which illustrate the method (Part 2).

FIGS. 33A-33B are sectional views of the semiconductor device according to the fourth embodiment of the present invention in the steps of the method for fabricating the same, which illustrate the method (Part 3).

FIGS. 34A-34B are sectional views of the semiconductor device according to the fourth embodiment of the present invention in the steps of the method for fabricating the same, which illustrate the method (Part 4).

FIGS. 35A-35B are sectional views of the semiconductor device according to the fourth embodiment of the present invention in the steps of the method for fabricating the same, which illustrate the method (Part 5).

### DESCRIPTION OF THE REFERENCE NUMBERS

10 . . . silicon substrate
12 . . . Ni film
14 . . . Ni₂Si film
16 . . . NiSi film
18 . . . NiSi₂ crystal
20 . . . silicon substrate
22 . . . gate insulation film
24 . . . gate electrode
26 . . . sidewall insulation film
28 . . . source/drain diffused layer
30 . . . NiSi film
32 . . . NiSi₂ crystal
34 . . . silicon substrate
36 . . . silicon oxide film
38 . . . photoresist film
40 . . . well
42 . . . silicon nitride film
44 . . . trench
46 . . . device isolation region
48 . . . photoresist film
50 . . . channel doped layer
52 . . . gate insulation film
54, 54n, 54p . . . gate electrode
56 . . . photoresist film
58, 58n, 58p . . . impurity diffused region
60 . . . sidewall insulation film
62, 62n, 62p . . . impurity diffused region
64, 64n, 64p . . . source/drain diffused layer
66 . . . Ni film
68 . . . protection film
70a, 70b . . . Ni₂Si film
72a, 72b . . . NiSi film
74 . . . silicon nitride film
76 . . . silicon oxide film
78a, 78b . . . contact hole
80 . . . barrier metal
82 . . . tungsten film
84a, 84b . . . contact plug
86 . . . inter-layer insulation film
88 . . . source/drain diffused layer
90 . . . NiSi film
92 . . . NiSi₂ crystal
94a, 94b . . . electrode pad
96 . . . NMOS transistor formed region
98 . . . PMOS transistor formed region
100a, 100b . . . Si₁₋ₓGeₓ film
101a, 101b . . . Ni₂Si₁₋ₓGeₓ film
102a, 102b . . . NiSi₁₋ₓGeₓ film
104 . . . hollow
106 . . . interconnection layer
108 . . . barrier metal
110 . . . copper film
112 . . . inter-layer insulation film
114 . . . interconnection layer
116 . . . barrier metal
118 . . . copper film
120 . . . electrode
122 . . . silicon oxide film
124a, 124b . . . Si_{1-x-y}GeₓC_{y} film
125a, 125b . . . Ni₂Si_{1-x-y}GeₓC_{y} film
126a, 126b . . . NiSi_{1-x-y}GeₓC_{y} film
128 . . . hollow
130 . . . silicon oxide film

### BEST MODE FOR CARRYING OUT THE INVENTION

[Principle of the Present Invention]

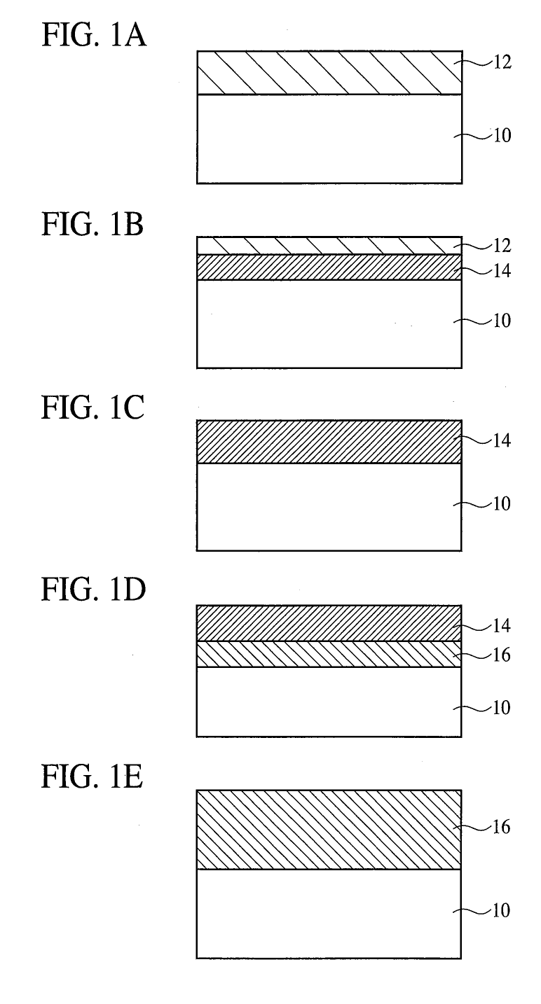

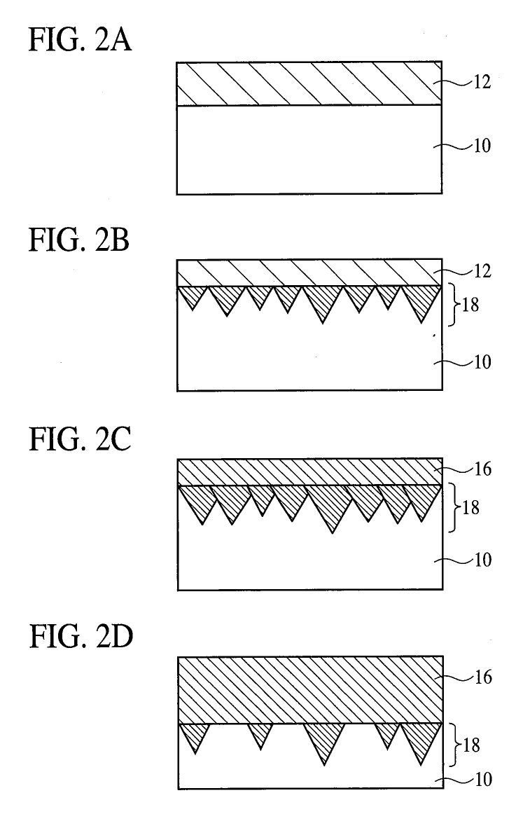

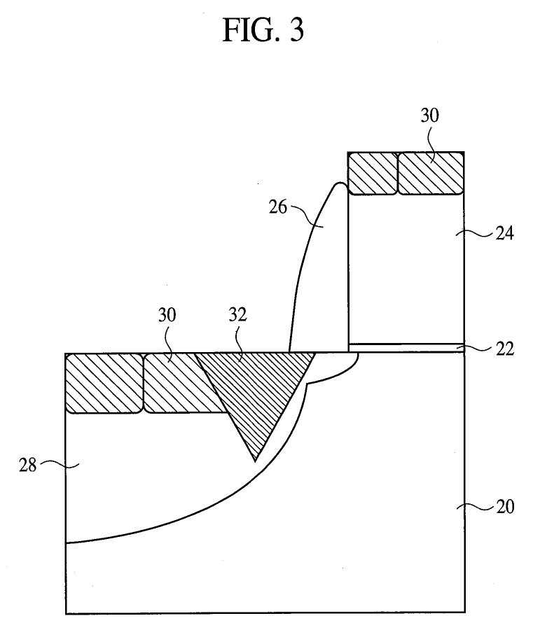

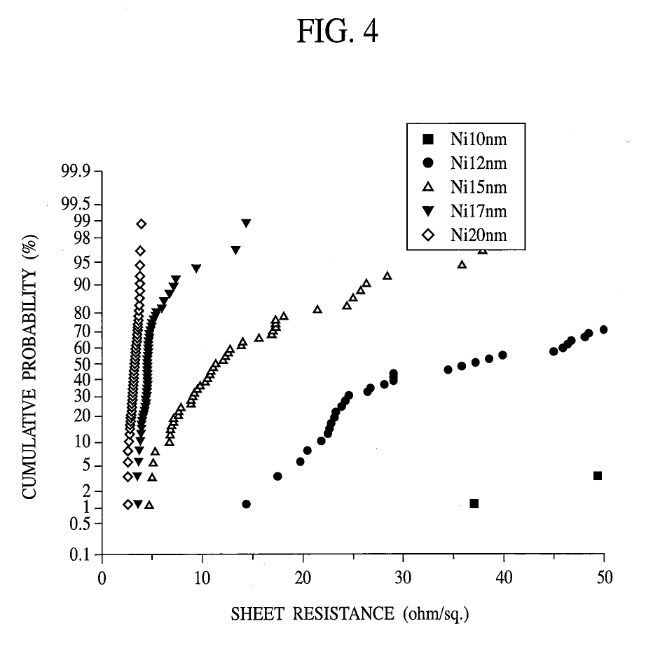

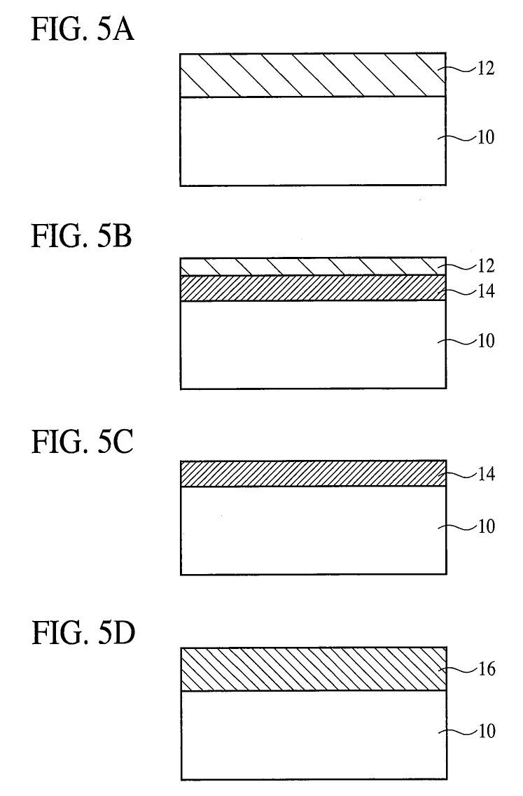

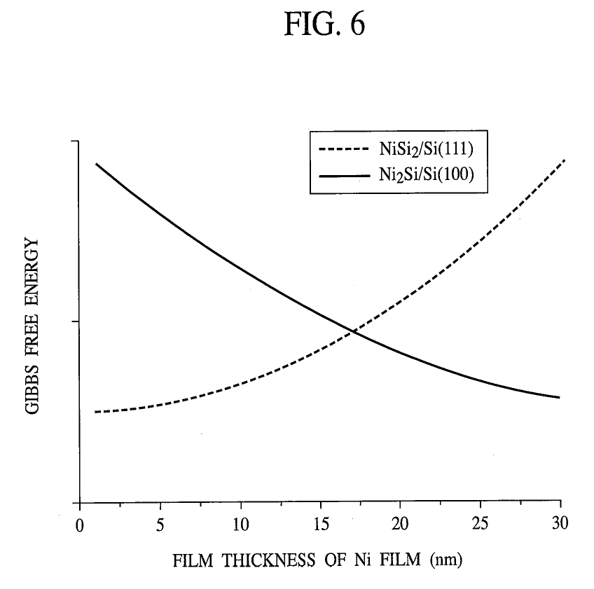

First, the principle of the present invention will be explained with reference to FIGS. 1A to 6. FIGS. 1A-1E and 2A-2D are diagrammatic sectional views illustrating reaction models of the silicidation process of nickel silicide. FIG. 3 is a diagrammatic sectional view of a structure of a MOS transistor subjected to the salicide process using a relatively thin Ni film. FIG. 4 is a graph of the result of the experiment of measuring sheet resistances of the source/drain diffused layers silicided using Ni film of different thicknesses. FIGS. 5A-5D are diagrammatic sectional views explaining the principle of the present invention. FIG. 6 is a graph schematically showing the relationship between the Gibbs free energy of the system formed of a silicon substrate and a nickel silicide film, and the film thickness of the Ni film.

As the reaction model of the silicidation process for forming nickel silicide of a silicon substrate and Ni film, different reaction models for the Ni film of different film thicknesses have so far reported. In the specification of the present application, “nickel silicide” widely means compounds of nickel and silicon, and to make a composition of nickel silicide explicit, “dinickel silicide (Ni₂Si)”, “nickel monosilicide (NiSi)” or “nickel disilicide (NiSi₂)” is discriminably used.

First, for the silicidation process in which a sufficiently thick Ni film of an about 200 nm-thickness is formed on a silicon substrate, and thermal processing is performed, the reaction model as described below has been reported (refer to F. d'Heurle, et al., J. Appl. Phys., vol. 55, pp. 4208-4218 (1984)).

When the thermal processing is performed with a nickel (Ni) film 12 of an about 200 nm-thickness formed on a silicon substrate 10 with face orientation (111) or (100) (see FIG. 1A), a dinickel silicide (Ni₂Si) film 14 is formed in the interface between the silicon substrate 10 and the Ni film 12 as illustrated in FIG. 1B. That is, a nickel silicide film 14 of Ni₂Si phase is formed in the interface between the silicon substrate 10 and the Ni film 12. The crystal of the Ni₂Si phase forming the nickel silicide film 14 is orthorhombic, the atomic composition ratio of the Ni:Si is 2:1, and the lattice constants are a=0.499 nm, b=0.372 nm and c=0.703 nm (refer to F. d'Heurle, et al., J. Appl. Phys., vol. 55, pp. 4208-4218 (1984)). The Ni₂Si film 14 is first formed, because the Ni film 12 is thick, and the supply of the Ni is larger in comparison with the supply of the Si.

Then, when the thermal processing is set on, the Ni₂Si film 14 grows as illustrated in FIG. 1C, and all the Ni becomes Ni₂Si. That is, the nickel silicide film 14 of Ni₂Si phase is formed on the silicon substrate 10.

Then, when the thermal processing is further set on, as illustrated in FIG. 1D, a nickel monosilicide (NiSi) film 16 is formed in the interface between the silicon substrate 10 and the Ni₂Si film 14. That is, the nickel silicide film 16 of NiSi phase is formed in the interface between the silicon substrate 10 and the nickel silicide film 14 of Ni₂Si phase. The crystal of NiSi phase forming the nickel silicide film 16 is orthorhombic, the atomic composition ratio of Ni:Si is 1:1, and the lattice constants are a=0.5233 nm, b=0.3258 nm and c=0.5659 nm (refer to F. d'Heurle, et al., J. Appl. Phys., vol. 55, pp. 4208-4218 (1984)).

Then, when the thermal processing is further set on, as illustrated in FIG. 1E, the NiSi film 16 further grows, and even the Ni₂Si film 14 becomes NiSi film. That is, a nickel silicide film 16 of only nickel silicide of NiSi phase alone is formed on the silicon substrate 10.

As described above, in the silicidation process using a sufficiently thick Ni film of an about 200 nm-thickness, the reaction advances in the order of Ni₂Si and NiSi.

On the other hand, the result of the section observation with a transmission electron microscope made for the case that a thin Ni film of a 12 nm-thickness is formed on a silicon substrate, and the thermal processing was performed has been reported (V. Teodorescu, et al., J. Appl. Phys., vol. 90, pp. 167-174 (2001)). The reaction model obtained by the observation with a transmission electron microscope is as follows.

When the thermal processing is performed with an Ni film 12 of an about 12 nm-thickness formed on a silicon substrate 10 with a face orientation (001) (see FIG. 2A), nickel disilicide (NiSi₂) crystals 18 are ununiformly formed in the interface between the silicon substrate 10 and the Ni film 12 as illustrated in FIG. 2B. That is, crystals of NiSi₂ phase are ununiformly formed in the interface between the silicon substrate 10 and the Ni film 12. The crystal of NiSi₂ phase is cubic, and the atomic composition ratio of Ni:Si is 1:2, the lattice constants are a=b=c=0.543 nm (refer to F. d'Heurle, et al., J. Appl. Phys., vol. 55, pp. 4208-4218 (1984)). As is not when the film thickness of the Ni film 12 is large, the NiSi₂ crystals 18 are formed at the early stage of the reaction, because the Ni film 12 is thin, and the supply of the Ni is smaller in comparison with the supply of the Si.

When the thermal processing is further set on, as illustrated in FIG. 2C, the Ni film 12 on the NiSi₂ crystals 18 becomes NiSi film 16. At this time, NiSi₂ crystals 18 grow in the silicon substrate 10. That is, on the silicon substrate 10, nickel silicide film having NiSi₂ phase and NiSi phase mixed is formed.

Then, when the thermal processing is further set on, as illustrated in FIG. 2D, NiSi film 16 grows. At this time, the NiSi₂ crystals 18 are formed ununiform below the NiSi film 16.

As described above, in the silicidation process using a relatively thin Ni film of an about 12 nm-thickness, the reaction advances in the order of NiSi₂ and NiSi, and NiSi₂ crystals are formed ununiform below the NiSi film.

As described above, depending on film thicknesses of the Ni film formed on the silicon substrate, the reaction process of the silicidation differs.

When the thermal processing is performed with a relatively thick Ni film of an about 200 nm-thickness, as described above, the reaction advances in the order of Ni₂Si and NiSi, and NiSi film can be formed uniform. The roughness in the interface between the silicon substrate and the NiSi film becomes small. However, as the semiconductor device is increasingly fined, the height of the gate electrode is below 100 nm including 100 nm, and the junction depth of the source/drain diffused layer is small. When the source/drain diffused layer of such small junction depth is silicided with a thick Ni film, an NiSi film the film thickness of which is too large relative to the junction depth is formed on the source/drain diffused layer. With an NiSi film which is too thick relative to a junction depth formed on the source/drain diffused layer, the junction leak current is increased.

On the other hand, when the thermal processing is performed with a relatively thin Ni film of an about 12 nm-thickness, as described above, an NiSi film is formed, and NiSi₂ crystals are also formed ununiform below the NiSi film. Here, the specific resistance of the NiSi is 14 μΩ·cm, and the specific resistance of the NiSi₂ is 34 μΩ·cm which is more than twice the specific resistance of the NiSi.

The NiSi₂ crystals of high resistance thus formed ununiform increase the roughness in the interface between the silicon substrate and the NiSi film, which is a cause for the scatter increase of the sheet resistance and is also a cause for the junction leak current increase.

FIG. 3 is a diagrammatic sectional view of a MOS transistor subjected to the salicide process using a relatively thin Ni film of an about 12 nm-thickness, which illustrates the structure thereof. As illustrated, a gate electrode 24 is formed on a silicon substrate 20 with a gate insulation film 22 formed therebetween. A sidewall insulation film 25 is formed on the side wall of the gate electrode 24. Source/drain diffused layers 28 of the extension source/drain structure are formed in the silicon substrate 20 on both sides of the gate electrode 24. NiSi films 30 by the salicide process using a relatively thin Ni film are formed on the gate electrode 24 and the source/drain diffused layers 28. By the salicide process, which uses a relatively thin Ni film, NiSi₂ crystals 32 are formed ununiform in the NiSi film 30 or below the NiSi film 30. That is, NiSi phase and NiSi₂ phase are mixed in the nickel silicide film.

Here, the source/drain diffused layer 28 has the junction depth smaller at a part near the end of the sidewall insulation film 26. Accordingly, as illustrated in FIG. 3, the NiSi₂ crystal 32 often arrives at the vicinity of the junction of the source/drain diffused layer 28. Such NiSi₂ crystal 32 is a cause for generating the junction leakage.

In the semiconductor device of the 90 nm-node technology, the junction depth of the source/drain diffused layer is below about 80 nm including 80 nm. Accordingly, the film thickness of a metal silicide film to be formed on the source/drain diffused layer as the source/drain electrode must be below 20 nm including 20 nm which can sufficiently suppress the generation of the junction leakage. Accordingly, the film thickness of the Ni film to be used in the silicidation of the source/drain diffused layer is preferably below about 13 nm including 13 nm. On the other hand, as described above, to form the Ni film thin forms the NiSi₂ crystals ununiform, which is a cause for the scatter of the sheet resistance and junction leak current. As described above, in siliciding a fine MOS transistor with Ni film, the conventional method does not allow the Ni film to be formed thick, and it will be difficult for the conventional method to prevent the formation of the NiSi₂ crystals which cause the deterioration of the transistor characteristics.

To specify the film thickness of the Ni film which permits the silicidation while suppressing the formation of the NiSi₂ crystals, the inventor of the present application made the experiment of measuring the sheet resistance of the source/drain diffused layer silicided with Ni film of different thicknesses. In the experiment, the surface of a 0.14 μm-width source/drain diffused layer doped with boron ions was silicided with Ni film of a 10 nm-thickness, a 12 nm-thickness, a 15 nm-thickness, 17 nm-thickness and a 20 nm-thickness. The sheet resistance was measured on a plurality of samples of the Ni film of each film thickness, and the cumulative probabilities of the samples were plotted. FIG. 4 is a graph of the result of the experiment. The sheet resistance of the source/drain diffused layer is taken on the horizontal axis and the cumulative probability is taken on the vertical axis. The plots indicated by the ▪ marks are for the case using the 10 nm-thickness Ni film. The plots indicated by the ● marks are for the case using the 12 nm-thickness Ni film. The plots indicated by the Δ marks are for the case using the 15 nm-thickness Ni film. The plots indicated by the ▾ marks are for the case using the 17 nm-thickness Ni film. The plots indicated by the ⋄ marks are for the 20 nm-thickness Ni film.

As evident based on the experiment result shown in FIG. 4, the scatter of the sheet resistance of the cases using the 17 nm-thickness Ni film and the 20 nm-thickness Ni film are much smaller in comparison with those of the cases using the 10 nm-thickness Ni film, 12 nm-thickness Ni film and the 15 nm-thickness Ni film. Based on this result, it is found that the formation of the NiSi₂ crystals is suppressed in the cases using the Ni film of above a 17 nm-thickness including 17 nm-thickness. That is, in this case, the silicidation will take place in accordance with the reaction model illustrated in FIGS. 1A-1E. When the film thickness of the Ni film is above 17 nm including 17 nm, the agglomeration of the silicide was also suppressed.

On the other hand, when the film thickness of the Ni film is below 17 nm excluding 17 nm, the scatter of the sheet resistance of the silicided source/drain diffused layer is conspicuous. Based on this result, when the film thickness of the Ni film is below 17 nm excluding 17 nm, it can be seen that the NiSi₂ crystals are formed. That is, in this case, the silicidation will take place in accordance with the reaction model illustrated in FIGS. 2A-2D.

The film thickness of the NiSi film formed from the Ni film of a film thickness of above 20 nm including 20 nm becomes above 30 nm including 30 nm. When the surface of the gate electrode and the surface of the source/drain diffused layer are simply silicided with Ni film of a thickness of above 20 nm including 20 nm, the formation of the NiSi₂ crystals is suppressed, but there is a risk that the junction leak current will be increased.

The inventor of the present application made earnest studies and have obtained an idea that the following method will be able to form the NiSi film in a required film thickness while suppressing the formation of the NiSi₂ crystals of high resistance. The silicidation process of the present invention will be explained with reference to FIGS. 5A-5D.

First, as illustrated in FIG. 5A, an Ni film 12 of, e.g., a 20 nm-thickness is formed on a silicon substrate 10. The film thickness of the Ni film 12 is, e.g., above 17 nm including 17 nm. However, as will be described later, a part of the Ni film 12, which has not reacted with Si, must be completely removed after the silicidation. It is preferable to set the film thickness of the Ni film 12 at below 200 nm including 200 nm at most.

Next, as the first thermal processing, thermal processing is performed by, e.g., RTA (Rapid Thermal Annealing) at 270° C. and for 30 seconds. Thus, as illustrated in FIG. 5B, the Ni in the lower part of the Ni film 12 and the Si in the upper part of the silicon substrate 10 are reacted with each other to form an Ni₂Si film 14. That is, the nickel silicide film 14 formed of only nickel silicide of Ni₂Si phase alone is formed in the interface between the silicon substrate 10 and the Ni film 12. The film thickness of the lower part of the Ni film 12 which is reacted with the Si is, e.g., 10 nm. The thermal processing temperature of the first thermal processing is, e.g., 200-400° C. The thermal processing period of time is, e.g., 10 seconds-60 minutes.

Then, as illustrated in FIG. 5C, the part of the Ni film 12 which has not reacted with the Si is selectively removed by etching. The etchant is, e.g., sulfuric acid/hydrogen peroxide mixture mixing sulfuric acid and hydrogen peroxide by 3:1. The etching period of time is set corresponding to a film thickness, etc. of the part of the Ni film 12, which has not reacted with the Si. For example, the etching period of time is 1-30 minutes.

Then, as the second thermal processing, thermal processing is performed by, e.g., RTA at 500° C. for 30 seconds. Thus, as illustrated in FIG. 5D, the Ni₂Si in the Ni₂Si film 14 and the Si in the upper part of the silicon substrate 10 are reacted with each other to form an NiSi film 16. That is, a nickel silicide film 16 formed of only nickel silicide of NiSi phase alone is formed on the silicon substrate 10. The thermal processing temperature of the second thermal processing is substantially equal to or higher than the thermal processing temperature of the first thermal processing, specifically, e.g., 350-650° C. The thermal processing period of time is, e.g., 10 seconds-60 minutes.

As described above, in the silicidation of the present invention, the lower part of the relatively thick Ni film 12 and the upper part of the silicon substrate 10 are reacted with each other by the first thermal processing. The relatively thick Ni film 12 is used, whereby by the first thermal processing, the Ni₂Si film 14 can be formed while the formation of the NiSi₂ crystals is being suppressed. After the part of the Ni film 12 which has not reacted with the Si is selectively removed by etching, the Ni₂Si film 14 and the upper part of the silicon substrate 10 are reacted with each other to form the NiSi film 16, whereby the NiSi film 16 is prevented from being formed too thick. The film thickness of the NiSi film can be controlled by suitably setting conditions such as the thermal processing temperatures and the thermal processing periods of time of the first thermal processing and the second thermal processing, etc.

Thus, the NiSi film 16 of low resistance and good quality can be formed in a required film thickness on the silicon substrate 10 while the formation of the NiSi₂ film of high resistance is being suppressed, and the roughness in the interface between the silicon substrate 10 and the NiSi film 16 can be made small. Thus, when the surface of the gate electrode and the surface of the source/drain diffused layer are silicided, the scatter of the sheet resistance can be suppressed. The junction leak current can be suppressed.

To form the Ni₂Si film by the first thermal processing while suppressing the formation of the NiSi₂ film, it is preferable to set the film thickness of the Ni film at above 17 nm including 17 nm. The reason for this is as follows.

FIG. 6 is a graph schematically showing the relationship between the Gibbs free energy of the system formed of a silicon substrate and nickel silicide film and the film thickness of the Ni film used in the silicidation. In the graph, the broken curve indicates the relationship between the Gibbs free energy of the system formed of a silicon substrate and NiSi₂ film and the film thickness of the Ni film used in the silicidation. In the graph, the solid curve indicates the relationship between the Gibbs free energy of the system formed of a silicon substrate and Ni₂Si film and the film thickness of Ni film used in the silicidation.

As shown in the graph of FIG. 6, with about 17 nm of the film thickness of the Ni film as the boundary, when the film thickness of the Ni film is smaller than the boundary film thickness, the system formed of the silicon substrate and the NiSi₂ film will have a lower Gibbs free energy than the system formed of the silicon substrate and the Ni₂Si film, and in this case, the NiSi₂ film will be stably formed.

On the other hand, with about 17 nm of the film thickness of the Ni film as the boundary, when the film thickness of the Ni film is larger than the boundary film thickness, the system formed of the silicon substrate and the Ni₂Si film will have a smaller Gibbs free energy than the system formed of the silicon substrate and the NiSi₂ film, and in this case, the Ni₂Si film will be formed stably. That is, the film thickness of the Ni film is set at above 17 nm including 17 nm, whereby the formation of the NiSi₂ film will be able to be sufficiently suppressed.

As described above, the film thickness of the Ni film is set at above 17 nm including 17 nm, more preferably above 20 nm including 20 nm, whereby by the first thermal processing, the Ni₂Si film will be able to be formed while suppressing the formation of the NiSi₂ film. This can be endorsed by the result of measuring the sheet resistance of the source/drain diffused layer shown in FIG. 4.

### A FIRST EMBODIMENT

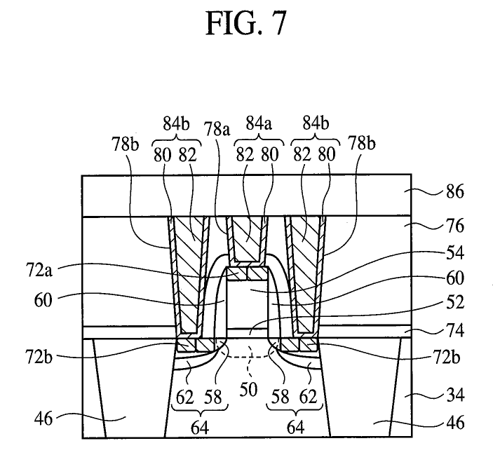

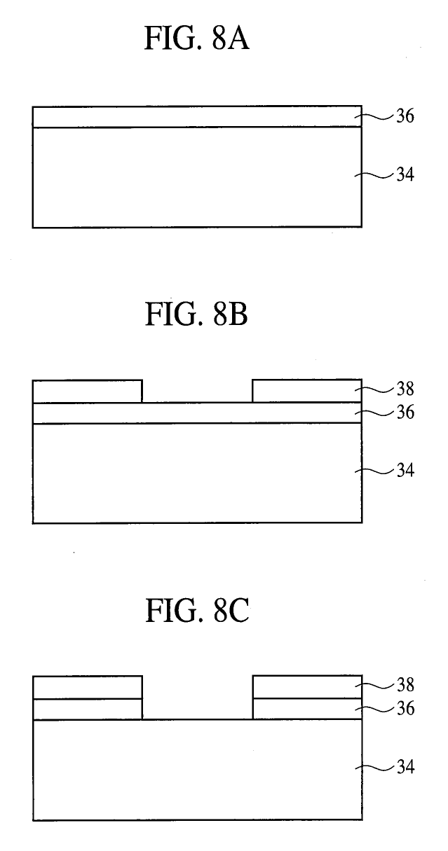

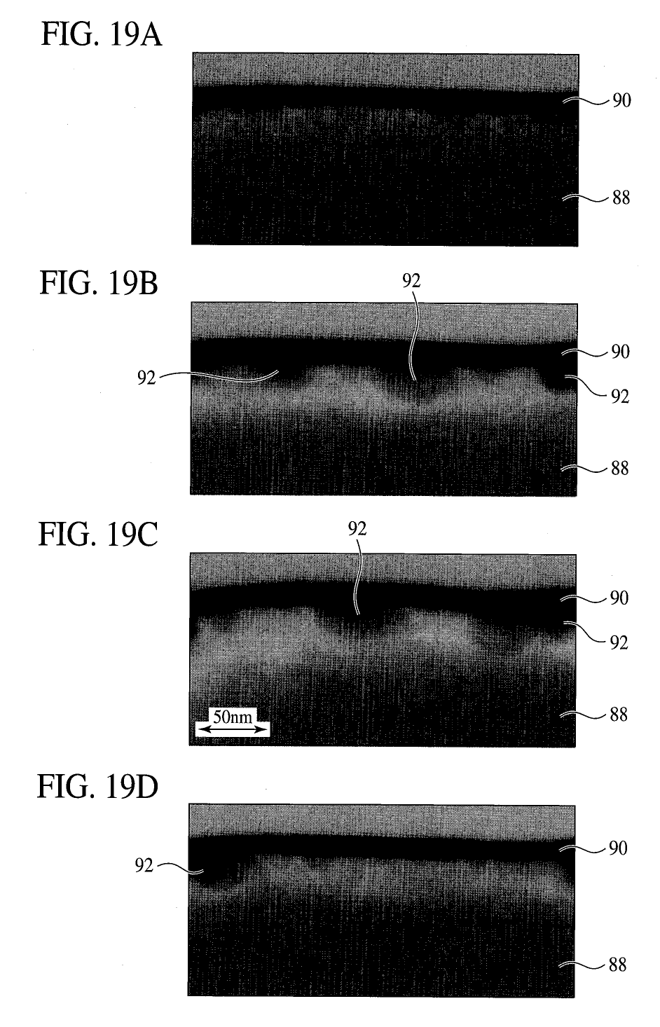

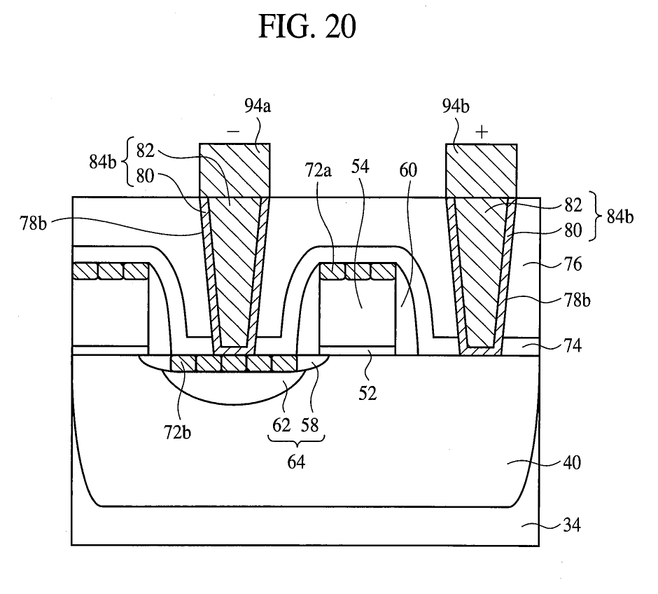

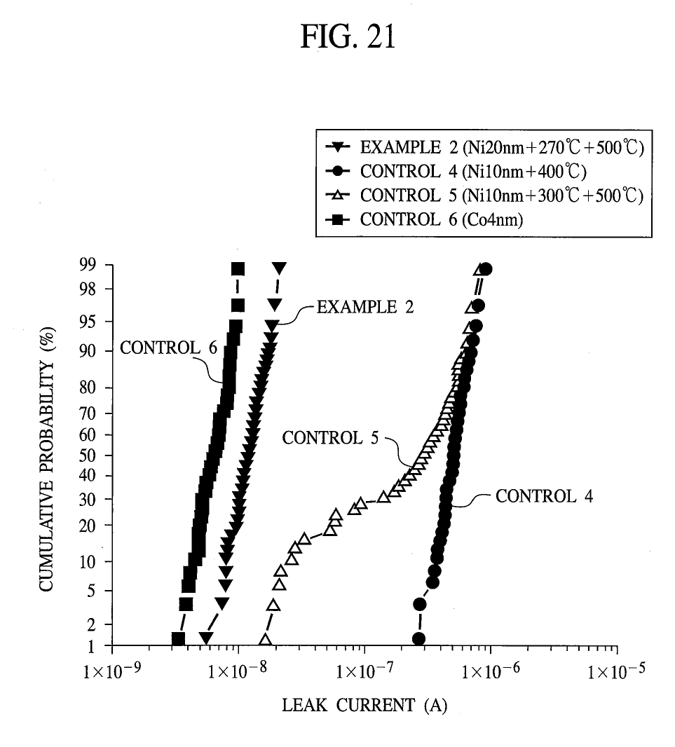

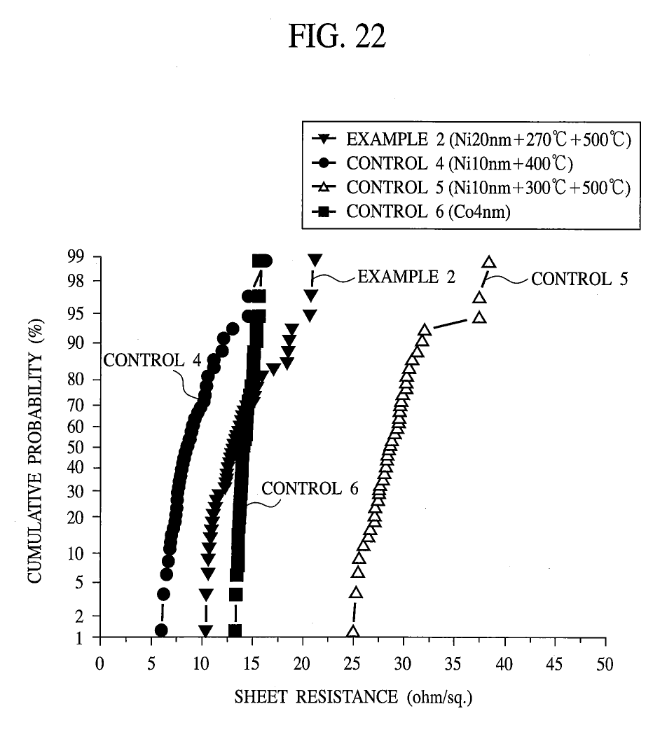

The semiconductor device and the method for fabricating the same according to a first embodiment of the present invention will be explained with reference to FIGS. 7 to 22. FIG. 7 is a sectional view of the semiconductor device according to the present embodiment, which illustrates a structure thereof. FIGS. 8A-8C to 18A-18C are sectional views of the semiconductor device according to the present embodiment in the steps of the method for fabricating the same, which illustrate the method. FIGS. 19A-19D are transmission electron microscopic pictures of the result of evaluating the method for fabricating the semiconductor device according to the present embodiment. FIG. 20 is a sectional view of the semiconductor device used in evaluating the method for fabricating the semiconductor device according to the present embodiment. FIGS. 21 and 22 are graphs showing the results of evaluating the method for fabricating the semiconductor device according to the present embodiment.

First, the structure of the semiconductor device according to the present embodiment will be explained with reference to FIG. 7.

A device isolation region 46 for defining a device region is formed in a silicon substrate 34. A well (not illustrated) is formed in the silicon substrate 34 with the device isolation region 46 formed in.

On the silicon substrate 34 with the well formed in, a gate electrode 54 of polysilicon film is formed with a gate insulation film 52 of a silicon oxide film formed therebetween. A nickel silicide film 72a of NiSi alone is formed on the gate electrode 54. That is, the nickel silicide film 72a is formed of only nickel silicide of NiSi phase alone. The film thickness of the nickel silicide film 72a is, e.g., below 20 nm including 20 nm.

A sidewall insulation film 60 is formed on the side wall of the gate electrode 54 with the nickel silicide film 72a formed on.

A channel doped layer 50 is formed in the silicon substrate 34 below the gate electrode 54. In the silicon substrate 34 on both sides of the gate electrode 54, source/drain diffused layers 64 formed of a shallow impurity diffused region 58 forming the extension region of the extension source/drain structure and a deep impurity diffused region 62 are formed. On the source/drain diffused layers 64, nickel silicide films 72b of NiSi alone are formed. That is, the nickel silicide film 72b is formed of only nickel silicide of NiSi phase alone. The film thickness of the nickel silicide film 72b is, e.g., below 20 nm including 20 nm.

Thus, a MOS transistor including the gate electrode 54 and the source/drain diffused layers 64 is formed on the silicon substrate 34.

On the silicon substrate 34 with the MOS transistor formed on, a silicon nitride film 74 is formed. On the silicon nitride film 74, a silicon oxide film 76 is formed.

In the silicon oxide film 76 and the silicon nitride film 74, a contact hole 78a is formed down to the nickel silicide film 72a on the gate electrode 54. In the silicon oxide film 76 and the silicon nitride film 74, contact holes 78b are formed down to the nickel silicide films 72b on the source/drain diffused layers 64.

In the contact holes 78a, 78b, contact plugs 84a, 84b of a barrier metal 80 and a tungsten film 82 are respectively buried.

An inter-layer insulation film 86 is formed on the silicon oxide film 76 with the contact plugs 84a, 84b buried in.

Thus, the semiconductor device according to the present embodiment is constituted.

The semiconductor device according to the present embodiment is characterized mainly in that the nickel silicide films 72a, 72b formed respectively on the gate electrode 54 and the source/drain diffused layers 64 are formed of only nickel silicide of NiSi phase alone.

That is, in the semiconductor device according to the present embodiment, no NiSi₂ crystals are formed in the nickel silicide films 72a, 72b. No NiSi₂ crystals are formed either in the interface between the nickel silicide film 72a and the gate electrode 54 and in the interfaces between the nickel silicide films 72b and the silicon substrate 34.

As described above, the nickel silicide films 72a, 72b are formed of only nickel silicide of NiSi phase alone, whereby the roughness in the interface between the NiSi film 72a and the gate electrode 54 and in the interfaces between the NiSi films 72b and the source/drain diffused layers 64 can be made small, and the scatter of the sheet resistances of the surface of the gate electrode 54 and the surfaces of the source/drain diffused layers 64 can be suppressed.

The film thickness of the nickel silicide film 72b is as thin as, e.g., below 20 nm including 20 nm, and furthermore, the NiSi₂ crystals, which are a cause for generating the junction leakage are not formed down to the vicinity of the junctions of the source/drain diffused layers 64, whereby even when the junction depths of the source/drain diffused layers 64 are shallow, the junction leak current can be suppressed.

Next, the method for fabricating the semiconductor device according to the present embodiment will be explained with reference to FIGS. 8A to 18C.

First, the surface of the silicon substrate 34 is cleaned with, e.g., ammonia/hydrogen peroxide mixture. The silicon substrate 34 is, e.g., a p type silicon substrate with face orientation (100).

Next, on the silicon substrate 34, a silicon oxide film 36 of, e.g., a 50 nm-thickness is formed by, e.g., thermal oxidation (see FIG. 8A).

Next, a photoresist film 38 is formed by, e.g., spin coating. Then, the photoresist film 38 is patterned by photolithography. Thus, the photoresist mask 38 for patterning the silicon oxide film 36 is formed (see FIG. 8B).

Next, with the photoresist film 36 as the mask, the silicon oxide film 36 is etched (see FIG. 8C).

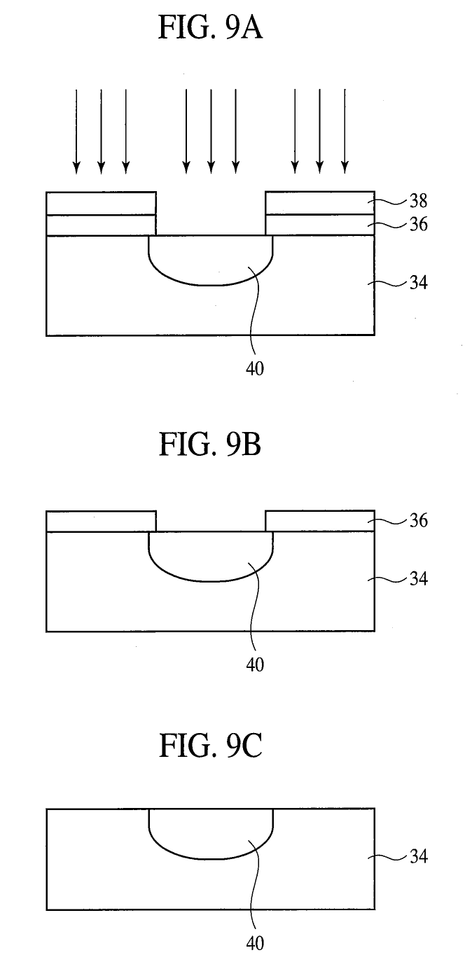

Next, with the photoresist film 38 and the silicon oxide film 36 as the mask, a dopant impurity is implanted into the silicon substrate 34 by, e.g., ion implantation. Thus, the well 40 of a prescribed conduction type is formed (see FIG. 9A). To form the p type well for forming an NMOS transistor, boron, for example, is used as the p type dopant impurity, and the conditions for the ion implanting are a 120 keV acceleration voltage and a 1×10¹³ cm⁻² dose. To form an n type well for forming a PMOS transistor, phosphorus, for example, is used as the n type dopant impurity, and the conditions for the ion implantation are, e.g., a 300 keV acceleration voltage and a 1×10¹³ cm⁻².

After the well 40 has been formed, the photoresist film 38 is removed (see FIG. 9B). Then, the silicon oxide film 36 is etched off (see FIG. 9C).

Next, the device isolation region for defining a device region is formed by, e.g., STI (Shallow Trench Isolation) as follows.

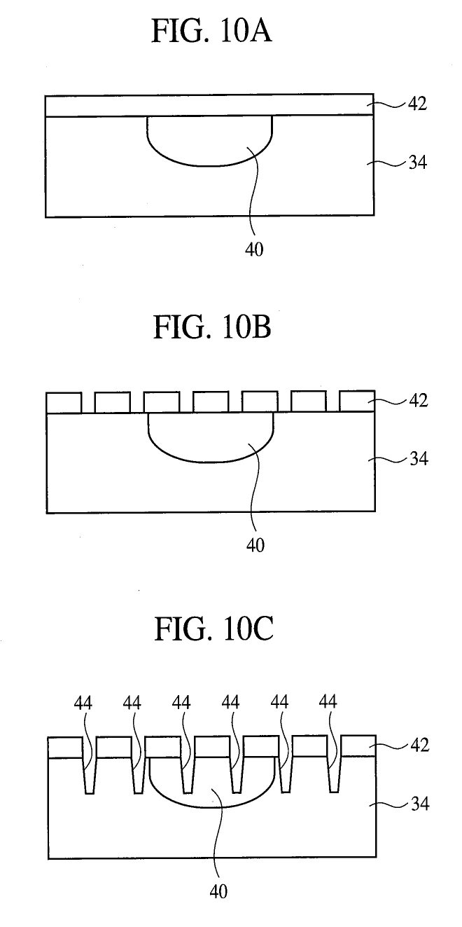

First, a silicon nitride film 42 of, e.g., a 50 nm-thickness is formed on the silicon substrate 34 by, e.g., CVD (Chemical Vapor Deposition) (see FIG. 10A).

Next, the silicon nitride film 42 is patterned by photolithography and dry etching. Thus, the hard mask 42 for forming the trench for the silicon oxide film to be buried in is formed (see FIG. 10B).

Next, with the silicon nitride film 42 as the mask, the silicon substrate 34 is etched. Thus, trenches 44 are formed in the silicon substrate 34 (see FIG. 10C).

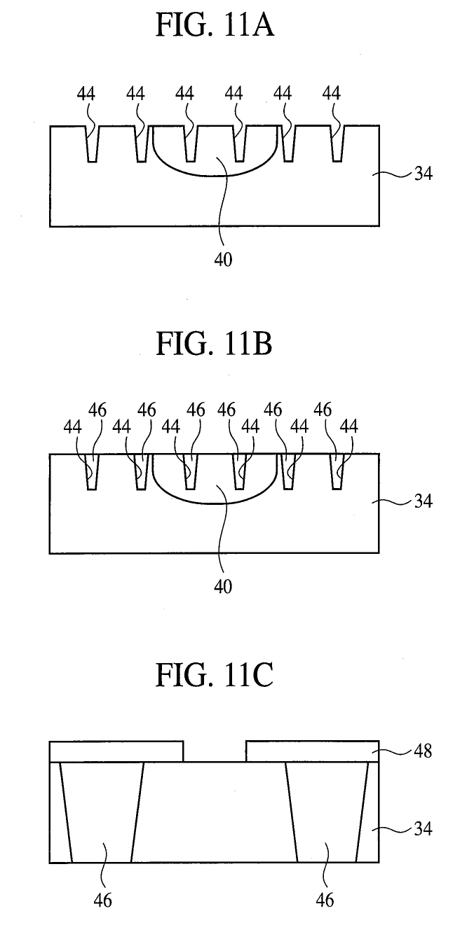

After the trenches 44 have been formed, the silicon nitride film 42 used as the mask is removed by, e.g., wet etching (see FIG. 11A).

Next, on the silicon substrate 34 with the trenches 44 formed in, a silicon oxide film of, e.g., a 30 nm-thickness is formed by, e.g., CVD.

Next, the silicon oxide film is polished by, e.g., CMP (Chemical Mechanical Polishing) until the surface of the silicon substrate 34 is exposed to remove the silicon oxide film on the silicon substrate 34.

Thus, the device isolation regions 46 of the silicon oxide film buried in the trenches 44 are formed (see FIG. 11B). The device isolation regions 46 define device regions.

Next, a photoresist film 48 is formed by, e.g., spin coating. Then, the photoresist film 48 is patterned by photolithography. Thus, the photoresist mask 48 for forming the channel doped layer is formed (see FIG. 11C). In FIG. 11C and the followers, the device region where a MOS transistor is to be formed in is enlarged.

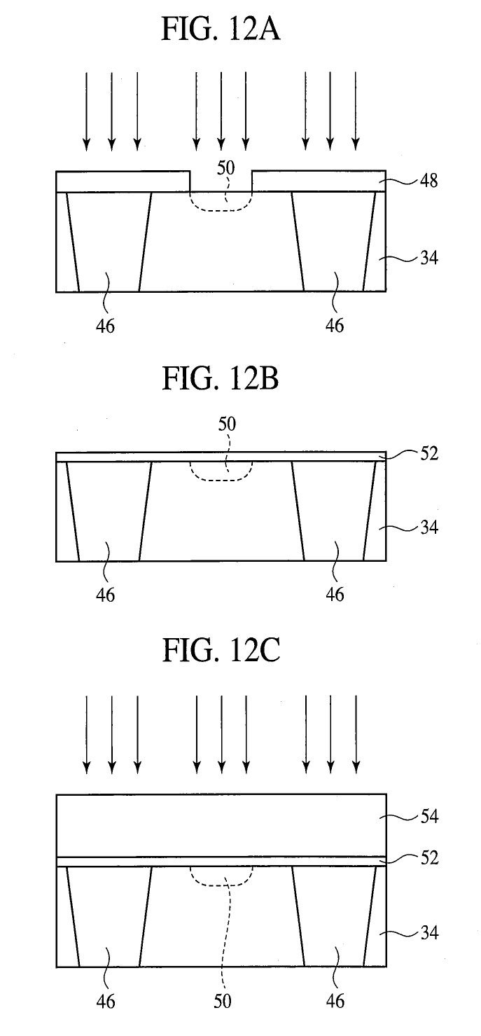

Next, with the photoresist film 48 as the mask, a dopant impurity is implanted into the silicon substrate 34 by, e.g., ion implantation. Thus, the channel doped layer 50 is formed in the silicon substrate 34 (see FIG. 12A). To form the NMOS transistor, boron, for example, is used as the p type dopant impurity, and the conditions for the ion implantation are, e.g., a 15 keV and a 1×10¹³ cm⁻² dose. To form the PMOS transistor, arsenic, for example, is used as the n type dopant impurity, and the conditions for the ion implantation are, e.g., an 80 keV acceleration voltage and a 1×10¹³ cm⁻² dose.

After the channel doped layer 50 has been formed, the photoresist film 48 used as the mask is removed.

Next, the dopant impurity in the channel doped layer 50 is activated by thermal processing of, e.g., 950° C. and 10 seconds.

Then, on the silicon substrate 34, the gate insulation film 52 of a silicon oxide film of, e.g., a 2 nm-thickness is formed by, e.g., thermal oxidation (see FIG. 12B). The gate insulation film 52 is formed of silicon oxide film but is not formed essentially of silicon oxide film. The gate insulation film 52 can be formed suitably of any other insulation film.

Next, a polysilicon film 54 of, e.g., a 100 nm-thickness is formed on the entire surface by, e.g., CVD.

Next, a dopant impurity is implanted into the polysilicon film 54 by, e.g., ion implantation (see FIG. 12C). To form the NMOS transistor, phosphorus, for example, is used as the n type dopant impurity, and the conditions for the ion implantation are, e.g., a 10 keV acceleration energy and a 1×10¹⁶ cm⁻² dose. To form the PMOS transistor, boron, for example, is used as the p type dopant impurity, and the conditions for the ion implantation are, e.g., a 5 keV acceleration energy and a 5×10¹⁵ cm⁻² dose.

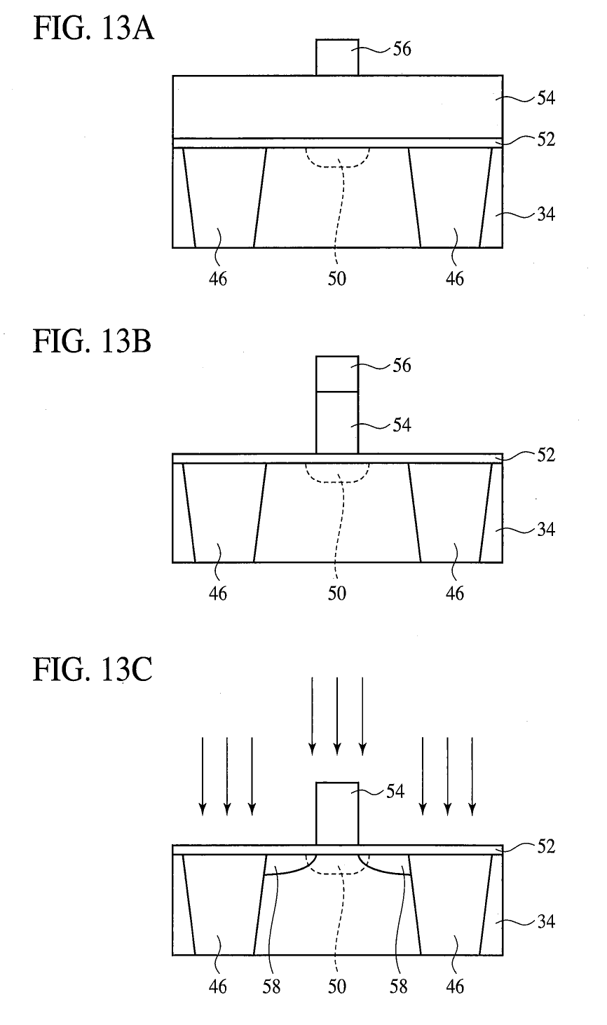

Next, a photoresist film 56 is formed by, e.g., spin coating. Then, the photoresist film 56 is patterned by photolithography. Thus, the photoresist mask 56 for patterning the polysilicon film 54 is formed (see FIG. 13A).

Then, with the photoresist film 56 as the mask, the polysilicon film 54 is dry etched. Thus, the gate electrode 54 of polysilicon film is formed (see FIG. 13B).

After the gate electrode 54 has been formed, the photoresist film 56 used as the mask is removed.

Then, with the gate electrode 54 as the mask, a dopant impurity is implanted in the silicon substrate 34 on both sides of the gate electrode 54 by, e.g., ion implantation. To form the NMOS transistor, arsenic, for example, is used as the n type dopant impurity, and the conditions for the ion implantation are, e.g., a 1 keV acceleration voltage and a 1×10¹⁵ cm⁻² dose. To form the PMOS transistor, boron, for example, is used as the p type dopant impurity, and the conditions for the ion implantation are, e.g., 0.5 keV acceleration voltage and a 1×10¹⁵ cm⁻² dose. Thus, the shallow impurity diffused regions 58 forming the extension regions of the extension source/drain structure are formed (see FIG. 13C).

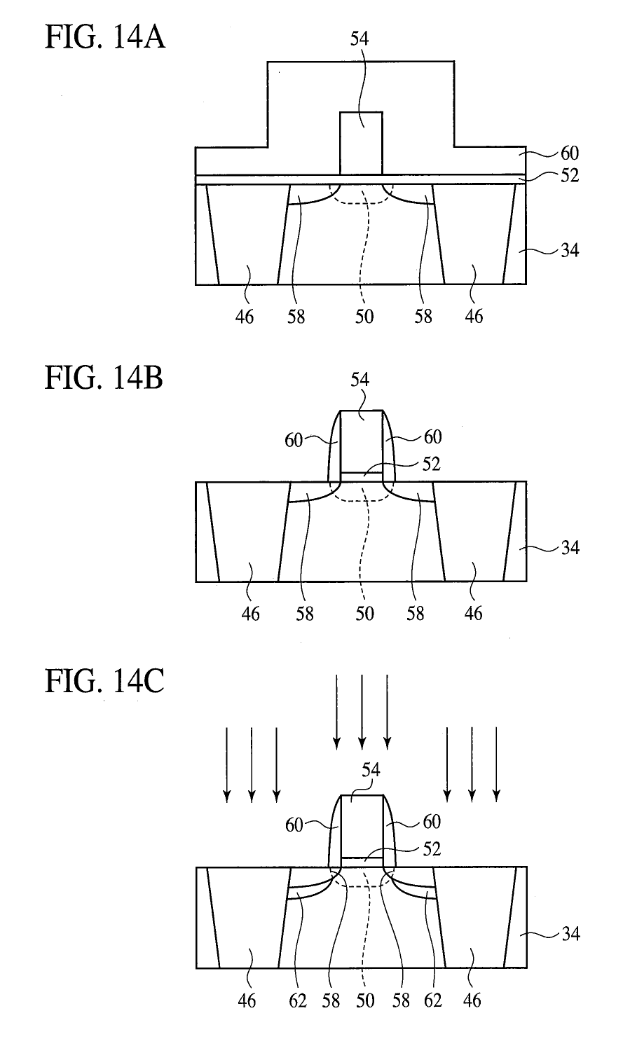

Next, a silicon oxide film 60 of, e.g., a 100 nm-thickness is formed on the entire surface by, e.g., CVD (see FIG. 14A).

Then, the silicon oxide film 60 is anisotropically etched by, e.g., RIE (Reactive Ion Etching). Thus, the sidewall insulation film 60 of silicon oxide film is formed on the side wall of the gate electrode 54 (see FIG. 14B). The sidewall insulation film 60 is formed of silicon oxide film here but is not formed essentially of silicon oxide film. The sidewall insulation film 60 can be formed suitably of any other insulation film.

Next, with the gate electrode 54 and the sidewall insulation film 60 as the mask, a dopant impurity is implanted in the silicon substrate 34 on both sides of the gate electrode 54 and the sidewall insulation film 60. To form the NMOS transistor, phosphorus, for example, is used as the n type dopant impurity, and the conditions for the ion implantation are an 8 keV acceleration voltage and a 1×10¹⁶ cm⁻² dose. To form the PMOS transistor, boron, for example, is used as the p type dopant impurity, and the conditions for the ion implantation are, e.g., a 5 keV acceleration voltage and a 5×10¹⁵ cm⁻² dose. Thus, the impurity diffused regions 62 forming the deep regions of the source/drain diffused layers are formed (see FIG. 14C).

Next, prescribed thermal processing is performed to activate the dopant impurities implanted in the impurity diffused regions 58, 62.

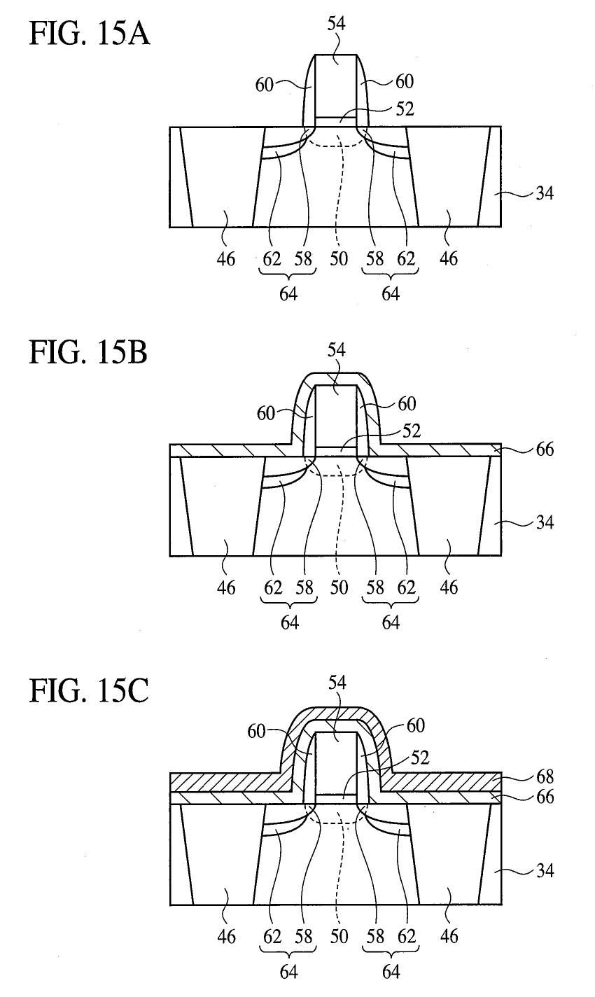

Thus, the source/drain diffused layers 64 formed of the extension region, i.e., the shallow impurity diffused region 58 and the deep impurity diffused region 62 are formed in the silicon substrate 34 on both sides of the gate electrode 54 (see FIG. 15A).

Next, a natural oxide film formed on the surface of the gate electrode 54 and the surfaces of the source/drain diffused layers 64 is removed by, e.g., hydrofluoric acid processing.

Next, an Ni film 66 of, e.g., a 20 nm-thickness is formed on the entire surface by, e.g., sputtering using an Ni target (see FIG. 15B). The film thickness of the Ni film 66 is above, e.g., 17 nm including 17 nm. As will be described later, the part of the Ni film 66, which has not reacted with Si, must be surely removed after the first thermal processing, and the film thickness of the Ni film 66 is preferably below 200 nm including 200 nm.

Then, a protection film 68 of a titanium nitride (TiN) film of, e.g., a 5-50 nm-thickness is formed on the Ni film 66 by, e.g., PVD (Physical Vapor Deposition) (see FIG. 15C). The protection film 68 is not essentially titanium nitride film. The protection film 68 can be a titanium (Ti) film of, e.g., a 5-30 nm-thickness.

The protection film 68 can prevent the oxidation of the nickel film 66 and a nickel silicide film to be formed later.

When the substrate with the Ni film 66 formed on is mounted on a cassette for transporting the substrate with the Ni film 66 exposed or is loaded in the furnace of the RTA apparatus or the chamber of the film forming apparatus, they are contaminated with the Ni, and the Ni particles often adhere to other substrates, etc. mounted on the cassette or loaded in the furnace of the RTA apparatus and the chamber of the film forming apparatus. The protection film 68 is formed on the Ni film 66, whereby such secondary contamination with the Ni can be prevented.

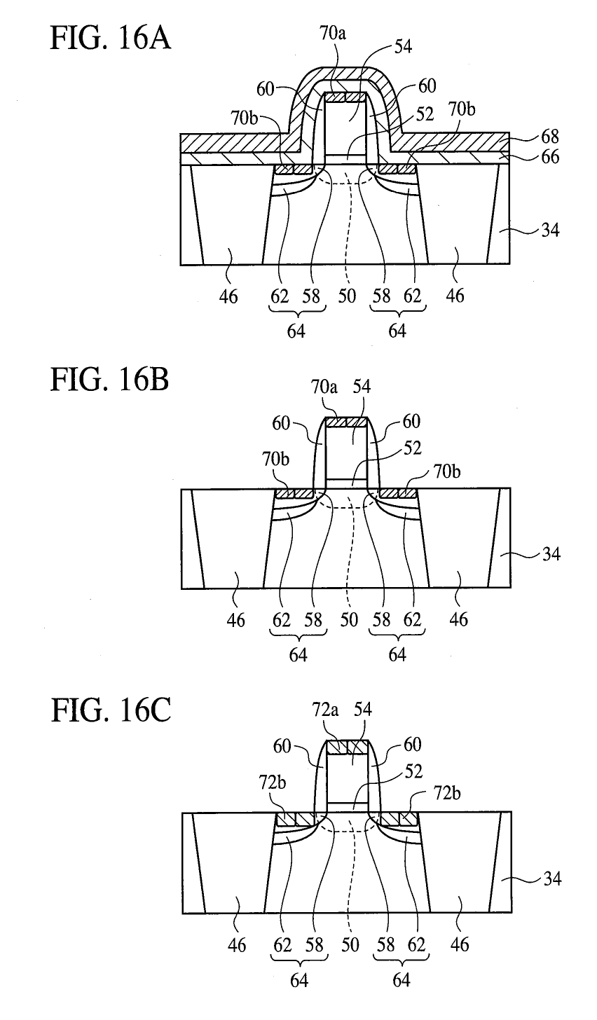

Then, as the first thermal processing for the silicidation, thermal processing of, e.g., 270° C. and 30 seconds is performed by, e.g., RTA. This thermal processing reacts the Ni in the lower part of the Ni film 66 with the Si in the upper part of the gate electrode 54 with each other and the Ni in the lower part of the Ni film 66 and the Si in the upper parts of the source/drain diffused layers 64 with each other. Thus, Ni₂Si films 70a, 70b are formed on the gate electrode 54 and on the source/drain diffused layers 64 (see FIG. 16A). That is, the nickel silicide films 70a, 70b formed of only nickel silicide of Ni₂Si phase alone are formed in the interface between the gate electrode 54 and the Ni film 66 and in the interface between the source/drain diffused layers 64 and the Ni film 66.

Then, the protection film 68 and the part of the Ni film 66, which have not reacted with the Si, are selectively removed, respectively (see FIG. 16B). The etchant is, e.g., sulfuric acid/hydrogen peroxide mixture mixing sulfuric acid and hydrogen peroxide by 3:1. The etching period of time is, e.g., 20 minutes.

Next, as the second thermal processing for the silicidation, thermal processing of, e.g., 500° C. and 30 seconds is performed by, e.g., RTA. This thermal processing reacts the Ni₂Si in the Ni₂Si film 70a and the Si in the upper part of the gate electrode 54 with each other and the Ni₂Si in the Ni₂Si films 70b and the Si in the upper parts of the source/drain diffused layers 64 with each other. Thus, the NiSi films 72a, 72b are formed on the gate electrode 54 and on the source/drain diffused layers 64 (see FIG. 16C). That is, the nickel silicide films 72a, 72b formed of only nickel silicide of NiSi phase alone are formed on the gate electrode 54 and on the source/drain diffused layers 64.

Thus, the NiSi film 72a, 72b are formed on the gate electrode 54 and on the source/drain diffused layers 64 by salicide process. The film thickness of the Ni film 66 and the conditions for the first and the second thermal processing are suitably set, whereby the NiSi films 72a, 72b of a required film thickness can be obtained. For example, the NiSi films 72a, 72b can have a film thickness of, e.g., below 20 nm including 20 nm.

As described above, the method for fabricating the semiconductor device according to the present embodiment is characterized mainly in that, after the Ni film 66 is formed relatively thick, the Si in the upper parts of the gate electrode 54 and the source/drain diffused layers 64 and the Ni in the lower part of the Ni film 66 are reacted with each other by the first thermal processing to form the Ni₂Si films 70a, 70b on the gate electrode 54 and the source/drain diffused layers 64, the part of the Ni film 66, which has not reacted with the Si, is selectively removed, and then the Si in the upper parts of the gate electrode 54 and the source/drain diffused layers and Ni₂Si in the Ni₂Si film 70a, 70b are reacted with each other by the second thermal processing to form the NiSi films 72a, 72b on the gate electrode 54 and the source/drain diffused layers 64.

By the first thermal processing, the Si in the upper parts of the gate electrode 54 and the upper part of the source/drain diffused layers 64 and the Ni in the lower part of the Ni film 66, which are formed relatively thick, are reacted with each other to form the Ni₂Si films 70a, 70b while suppressing the formation of NiSi₂ crystals in the first thermal processing. Then, after the part of the Ni film 66, which has not reacted with the Si, is selectively etched off, by the second thermal processing the Si in the upper part of the gate electrode 54 and the upper parts of the source/drain diffused layers 64 and the Ni₂Si in the Ni₂Si films 70a, 70b are reacted with each other to form the NiSi film 72a, 72b, whereby the NiSi films 72a, 72b are prevented from being formed too thick. The film thickness of the NiSi films 72a, 72b can be controlled by suitably setting the thermal processing temperature, the thermal processing period of time, etc. of the first and the second thermal processing.

Thus, on the gate electrode 54 and the source/drain diffused layer 64, the NiSi film 72a, 72b of good quality can be formed in a required film thickness while the formation of NiSi₂ crystals of high resistance is being suppressed. This makes it possible to decrease the roughness in the interface between the NiSi film 72a and the gate electrode 54 and in the interfaces between the NiSi films 72b and the source/drain diffused layers 64 and suppress the scatter of the sheet resistances of the surface of the gate electrode 54 and the surfaces of the source/drain diffused layers 64. The junction leak current can be suppressed.

Then, a silicon nitride film 74 of, e.g., a 50 nm-thickness is formed on the entire surface by, e.g., plasma CVD. The film forming temperature of the silicon nitride film 74 is, e.g., 500° C. The steps following the salicide process are performed at a temperature of, e.g., below 500° C. including 500° C. so as to suppress the agglomeration of the NiSi films 72a, 72b.

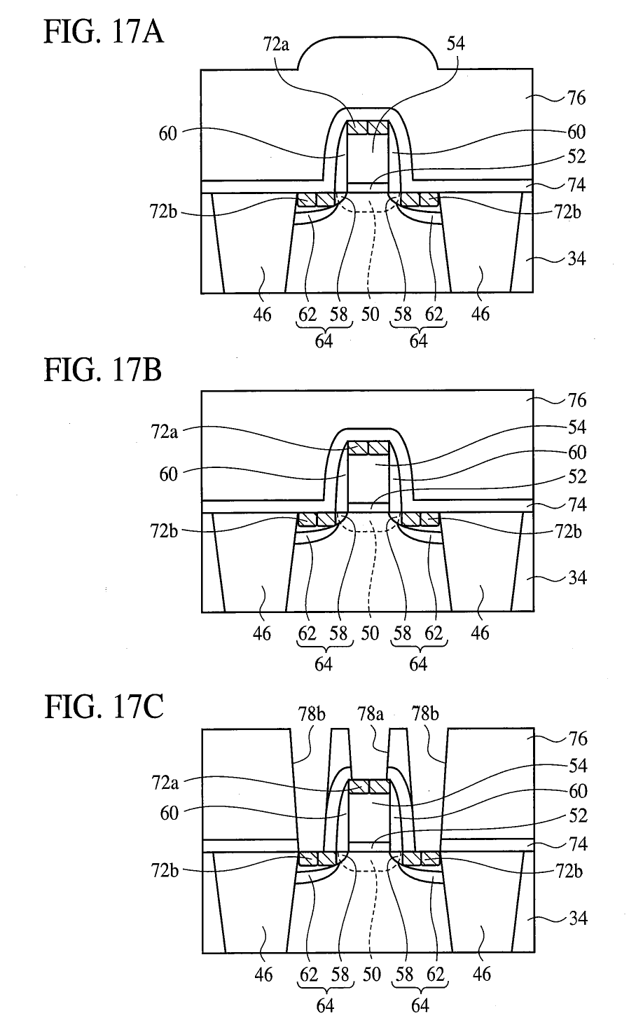

Next, on the silicon nitride film 74, a silicon oxide film 76 of, e.g., a 600 nm-thickness is formed by, e.g., plasma CVD (see FIG. 17A).

Then, the silicon oxide film 76 is planarized by, e.g., CMP (see FIG. 17B).

Next, by photolithography and dry etching, the contact hole 78a and the contact holes 78b are formed in the silicon oxide film 76 and the silicon nitride film 74 respectively down to the NiSi film 72a and down to the NiSi films 72b (see FIG. 17C).

Then, the barrier metal 80 of titanium nitride film of, e.g., a 50 nm-thickness is formed by, e.g., sputtering on the silicon oxide film 76 with the contact holes 78a, 78b formed in.

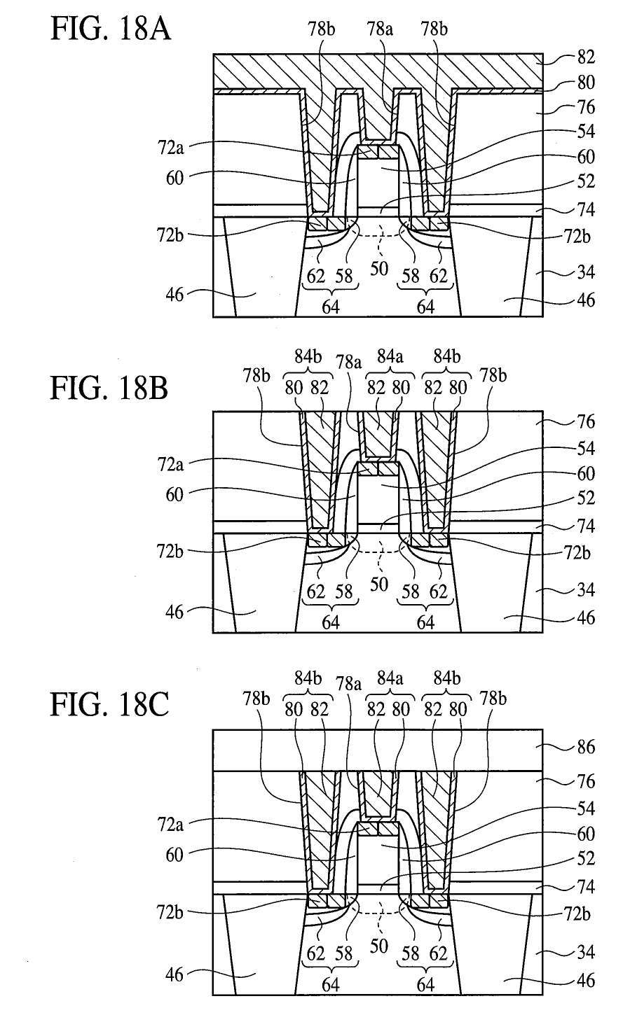

Next, the tungsten film 82 of, e.g., a 400 nm-thickness is formed on the barrier metal 80 by, e.g., CVD (see FIG. 18A).

Next, the tungsten film 82 and the barrier metal 80 are polished by, e.g., CMP until the surface of the silicon oxide film 76 is exposed. Thus, the contact plugs 84a, 84b of the barrier metal 80 and the tungsten film 82 are formed respectively in the contact holes 78a, 78b (see FIG. 18B).

Next, the inter-layer insulation film 86 is formed on the entire surface (see FIG. 18C).

After the inter-layer insulation film 86 has been formed, an interconnection layer (not illustrated) is suitably formed.

Thus, the semiconductor device according to the present embodiment shown in FIG. 7 is fabricated.

Next, the result of evaluating the method for fabricating the semiconductor device according to the present embodiment will be explained with reference to FIGS. 19A to 22.

(Result of the Evaluation (Part 1))

The MOS transistor fabricated by the method for fabricating the semiconductor device according to the present embodiment was sectionally observed with a transmission electron microscope to evaluate the roughness in the interface between the silicon substrate and the nickel silicide film. The sectional observation was made on the interface between the source/drain diffused layer of the MOS transistor and the nickel silicide film formed on the source/drain diffused layer.

FIG. 19A is a transmission electron microscopic picture of the result of the sectional observation of Example 1, i.e., the semiconductor device fabricated by the method for fabricating the semiconductor device according to the present embodiment. In Example 1, TiN film was formed on a 20 nm-thickness Ni film, and as the first thermal processing, thermal processing of 260° C. and 30 seconds was performed. Next, the TiN film and the part of the Ni film, which had not reacted with Si, were selectively removed, and then, thermal processing of 450° C. and 30 seconds was performed as the second thermal processing.

FIG. 19B is a transmission electron microscopic picture of the result of the sectional observation of Control 1. In Control 1, TiN film was formed on a 10 nm-thickness Ni film, and thermal processing of 400° C. and 30 seconds was performed once.

FIG. 19C is a transmission electron microscopic picture of the result of the sectional observation of Control 2. In Control 2, TiN film was formed on a 10 nm-thickness Ni film, and as the first thermal processing, thermal processing of 280° C. and 30 seconds was performed. Next, the TiN film and the part of the Ni film, which had not reacted with Si, were selectively removed, and then, thermal processing of 450° C. and 20 seconds was performed as the second thermal processing.

FIG. 19D is a transmission electron microscopic picture of the result of the sectional observation of Control 3. In Control 3, TiN film was formed on a 10 nm-thickness Ni film, and as the first thermal processing, thermal processing of 260° C. and 30 seconds was performed. Next, the TiN film and the part of the Ni film, which had not reacted with Si, were selectively removed, and then, thermal processing of 450° C. and 30 seconds was performed as the second thermal processing.

In Controls 1 to 3 shown in FIGS. 19B to 19D, NiSi₂ crystals 92 of high resistance are observed being ununiformly formed near the interface between the source/drain diffused layer 88 and the NiSi film 90. That is, in Controls 1 to 3, NiSi phase and NiSi₂ phase are mixed in the nickel silicide film formed on the source/drain diffused layer. The low-temperature annealing alone without forming the Ni film thick cannot suppress the NiSi₂ spikes.

In contrast to this, in Example 1 shown in FIG. 19A, such NiSi₂ crystals are not observed. That is, in Example 1, the nickel silicide film formed on the source/drain diffused layer is formed of only nickel silicide of NiSi phase alone.

As evident in the electron microscopic pictures shown in FIGS. 19A to 19D, it is found that in Example 1, the roughness in the interface between the source/drain diffused layer 88 and the NiSi film 90 is much smaller in comparison with those of Controls 1 to 3.

Based on the sectional observation with the transmission electron microscope, it is confirmed that the method for fabricating the semiconductor device according to the present embodiment can form NiSi film of good quality while suppressing the formation of NiSi₂ film and can decrease the roughness in the interface between the silicon substrate and the NiSi film.

(Evaluation Result (Part 2))

The junction leak current of the source/drain diffused layer was measured on the MOS transistor fabricated by the method for fabricating the semiconductor device according to the present embodiment. The junction leak current was measured on the p type source/drain diffused layer of the PMOS transistor, in which boron was ion implanted.

In the measurement, as illustrated in FIG. 20, negative voltage was applied via the contact plug 84b and the electrode pad 94a to the source/drain diffused layer 64 formed on the side of the gate electrode 54. Positive voltage was applied via the contact plug 84b and the electrode pad 94b to the n type well 40 on the other side of the gate electrode 54, where the source/drain diffused layer is not formed. Thus, the junction leak current which flows when inverse bias is applied between the source/drain diffused layer 64 and the well 40 with the gate electrode 54 positioned therebetween was measured. In Example 2 and Controls 4 to 6 which will be described below, the junction leak current was measured on a plurality of samples respectively of them, and the cumulative probabilities were plotted. FIG. 21 is a graph of the measurement result. The components of the junction leak current of the source/drain diffused layer near the gate electrode are taken on the horizontal axis, and the cumulative probabilities are taken on the vertical axis.

In FIG. 21, the plots indicated by the ▾ marks are of the measurement result of the Example 2, i.e., the semiconductor device fabricated by the method for fabricating the semiconductor device according to the present embodiment. In Example 2, TiN film was formed on a 20 nm-thickness Ni film, and as the first thermal processing, thermal processing of 270° C. and 30 seconds was performed. Next, the TiN film and the part of the Ni film, which had not reacted with Si, were selectively removed by cleaning with ammonia/hydrogen peroxide mixture and sulfuric acid/hydrogen peroxide mixture, and then thermal processing of 500° C. and 30 seconds was performed as the second thermal processing.

In FIG. 21, the plots indicated by the ● marks are of the measurement result of Control 4 in which Ni film was formed relatively thin, and thermal processing was performed only once. In Control 4, TiN film was formed on a 10 nm-thickness Ni film, and thermal processing of 400° C. and 30 seconds was performed once. Next, the TiN film and the part of the Ni film, which had not reacted with Si, were selectively removed by cleaning with ammonia/hydrogen peroxide mixture and sulfuric acid/hydrogen peroxide mixture.

In FIG. 21, the plots indicated by the A marks are of the measurement result of Control 5 in which Ni film was formed relatively thin, and thermal processing was performed twice. In Control 5, TiN film was formed on a 10 nm-thickness Ni film, and as the first thermal processing, thermal processing of 300° C. and 30 seconds was performed. Next, the TiN film and the part of the Ni film, which had not reacted with Si, were selectively removed by cleaning with ammonia/hydrogen peroxide mixture and sulfuric acid/hydrogen peroxide mixture, and then thermal processing of 500° C. and 30 seconds was performed as the second thermal processing.

In FIG. 21, the plots indicated by the ▪ marks are of the measurement result of Control 6 in which cobalt silicide (CoSi₂) film was formed in place of nickel silicide film. In Control 6, as the metal film for the silicidation, a 4 nm-thickness Co film was formed in place of Ni film, and the CoSi₂ film was formed by thermal processing.

As evident from the respective plots shown in FIG. 21, in Example 2, in which the Ni film was formed relatively thick in a 20 nm-thickness, and the temperature of the first thermal processing was set relatively low at 270° C., the junction leak current is very small in comparison with those of Controls 4 and 5, in which the Ni film was formed thin in a 10 nm-thickness. The junction leak current of Example 2 is decreased to be low comparably to that of Control 6, in which CoSi₂ film was formed.

Based on the results of Controls 4 and 5, it is found that when the Ni film is formed relatively thin, the junction leak current cannot be sufficiently decreased whether the temperature of the first thermal processing is high or low.

(Evaluation Result (Part 3))

Furthermore, the sheet resistance of the gate electrode was measured on the MOS transistor fabricated by the method for fabricating the semiconductor device according to the present embodiment. As the MOS transistor, the PMOS transistor was formed. The dopant impurity ion implanted in the gate electrode was boron. The gate length was 40 nm. The sheet resistance was measured on a plurality of samples respectively of Example 2 and Controls 4 to 6 described above, and the cumulative probabilities were plotted. FIG. 22 is a graph of the measured result. The sheet resistance was taken on the horizontal axis and the cumulative probability was taken on the vertical axis. In FIG. 22, the plots indicated by the ▾ marks are of the measured result of Example 2, the plots indicated by the ● marks are of the measured result of Control 4, the plots indicated by the Δ marks are of the measured result of Control 5, and the plots indicated by the ▪ marks are of the measured result of Control 6.

As evident from the comparison with the plots shown in FIG. 22, the sheet resistance of Example 2 is much lower in comparison with that of Control 5 having the Ni film formed relatively thin. The sheet resistance of Example 2 is substantially equal or lower than that of Control 6 having CoSi₂ film formed.

Based on the above-described measured results of the junction leak current and the sheet resistance, it is found that the method for fabricating the semiconductor device according to the present embodiment can decrease the junction leak current of the source/drain diffused layer and the sheet resistance of the upper part of the gate electrode, where the silicide film is formed.

As described above, according to the present embodiment, the Ni film 66 is formed relatively thick in above a prescribed thickness including the prescribed thickness, the lower part of the Ni film 66 is reacted with Si by the first thermal processing to form the Ni₂Si films 70a, 70b, and after the part of the Ni film 66, which has not reacted with Si, is removed, the Ni₂Si films 70a, 70b are reacted with Si by the second thermal processing to form the NiSi films 72a, 72b, whereby the NiSi film 72a, 72b of good quality can be formed in a prescribed film thickness while suppressing the formation of the NiSi₂ film of high resistance. Accordingly, the roughness in the interface between the gate electrode 54 and the NiSi film 72a and in the interfaces between the source/drain diffused layers 64 and the NiSi films 72b can be made small, and the scatter of the sheet resistances of the surface of the gate electrode 54 and the surface of the source/drain diffused layer 64 can be suppressed. The junction leak current can be suppressed.

(A Modification)

The method for fabricating the semiconductor device according to a modification of the present embodiment will be explained.

The method for fabricating the semiconductor device according to the present modification is characterized in that the steps from the step of forming the Ni film 66 to the step of performing the first thermal processing of the above-described method for fabricating the semiconductor device are made continuously without the exposure to the atmospheric air.

First, the steps up to the step of forming the source/drain diffused layers 64 are the same as those of the method for fabricating the semiconductor device illustrated in FIGS. 8A to FIG. 15A, and their explanation will be omitted.

Next, a natural oxide film formed on the surface of the gate electrode 54 and the surfaces of the source/drain diffused layers 64 is removed by, e.g., hydrofluoric acid processing.

Then, the Ni film 66 of, e.g., a 20 nm-thickness is formed on the entire surface. The film thickness of the Ni film 66 is above 17 nm including 17 nm. The part of the Ni film 66, which has not reacted with Si, must be completely removed after the silicidation, and the film thickness of the Ni film 66 is preferably below 200 nm including 200 nm.

To form the Ni film 66, a film forming apparatus which can form plural kinds of metal films and perform thermal processing in one and the same chamber without the exposure to the atmospheric air is used. The film forming methods for forming the metal films in such film forming apparatus are, e.g., sputtering, vapor deposition, etc. Thus, the formation of the Ni film 66 and the formation of the protection film 68 of TiN film or others formed on the Ni film, and the first thermal processing can be continuously without the exposure to the atmospheric air.

Then, the protection film 68 of, e.g., a 5-50 nm-thickness TiN film is formed on the Ni film 66 continuously in the chamber where the Ni film 66 has been formed. The protection 68 is not limited to titanium nitride film. The protection film 68 can be, e.g., Ti film of a 5-30 nm-thickness.

In the present modification, after the Ni film 66 has been formed, the protection film 68 is formed continuously in the chamber where the Ni film 66 has been formed without transporting the substrate and making processing in another apparatus, etc. with the Ni film 66 exposed. Accordingly, the secondary contamination with the Ni can be effectively prevented.

Then, as the first thermal processing for the silicidation, thermal processing is performed by, e.g., RTA of, e.g., 270° C. and 30 seconds continuously in the chamber where the Ni film 66 and the protection film 68 have been formed. Thus, the Ni in the lower part of the Ni film 66 and the Si in the upper part of the gate electrode 54 are reacted with each other, and the Ni in the lower part of the Ni film 66 and the Si in the upper parts of the source/drain diffused layers 64 are reacted with each other. Thus, the NiSi film 70a is formed on the gate electrode 54, and the NiSi films 70b are formed on the source/drain diffused layers 64.

The steps following the first thermal processing are the same as those of the method for fabricating the semiconductor device illustrated in FIGS. 16C to FIG. 18C, and their explanation will be omitted.

As described above, in the method for fabricating the semiconductor device according to the present modification, the steps from the step of forming the Ni film 66 to the step of performing the first thermal processing are continuously made in one and the same chamber of the apparatus without the exposure to the atmospheric air. Thus, the surface of the Ni film 66 is prevented from being oxidized, and silicide film of good quality can be formed. Another thermal processing apparatus for making the first thermal processing is not necessary, which can increase the throughput of the fabrication process.

The protection film 68 is formed continuously in the chamber where the Ni film 66 has been formed, whereby the secondary contamination with the Ni can be effectively prevented.

### A SECOND EMBODIMENT

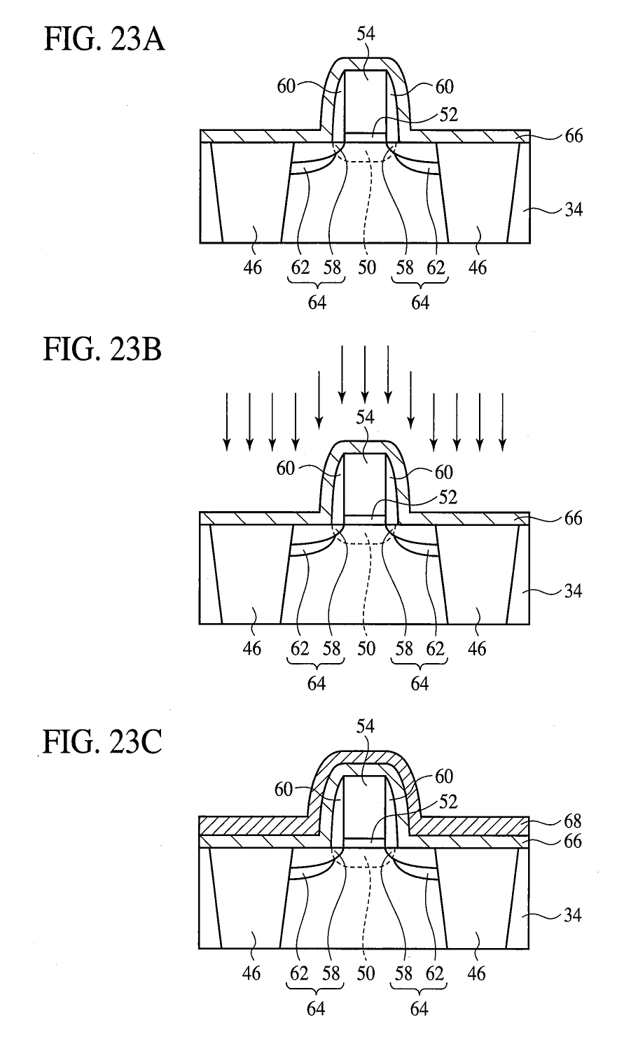

The semiconductor device and the method for fabricating the same according to a second embodiment of the present invention will be explained with reference to FIGS. 23A-23C. FIGS. 23A-23C is sectional views of the semiconductor device according to the present embodiment in the steps of the method for fabricating the same, which illustrate the method. The same members of the present embodiment as those of the semiconductor device and the method for fabricating the same according to the first embodiment illustrated in FIGS. 7 to 18C will be represented by the same reference numbers not to repeat or to simplify their explanation.

The semiconductor device according to the present embodiment is substantially the same in the structure as that of the semiconductor device according to the first embodiment but is different from the semiconductor device according to the first embodiment in the fabricating method.

That is, the method for fabricating the semiconductor device according to the present embodiment is characterized in that in the method for fabricating the semiconductor device according to the first embodiment, the Ni film 66 is amorphized by ion implantation of Ni ions before the first thermal processing for the silicidation.

The steps up to the step of forming the source/drain diffused layers 64 are the same as those of the method for fabricating the semiconductor device according to the first embodiment illustrated in FIGS. 8A to 15A, and their explanation will be omitted.

Next, a natural oxide film formed on the surface of the gate electrode 54 and the surfaces of the source/drain diffused layers 64 is removed by, e.g., hydrofluoric acid processing.

Then, an Ni film 66 of, e.g., a 20 nm-thickness is formed on the entire surface by, e.g., sputtering using an Ni target (see FIG. 23A). The film thickness of the Ni film 66 is above 17 nm including 17 nm. The film thickness of the Ni film 66 is preferably below 200 nm including 200 nm, because the part of the Ni film 66, which has not reacted with Si, must be surely removed after the silicidation.

Then, before the first thermal processing for the silicidation is performed, Ni ions are implanted into the Ni film 66 (see FIG. 23B). Thus, the Ni film 66 is amorphized. The conditions for implanting Ni ions are suitably set, depending on the film thickness of the Ni film 66. When the film thickness of the Ni film 66 is, e.g., 20 nm, as a condition for the ion implantation, the acceleration voltage is, e.g., 5 keV. When the film thickness of the Ni film 66 is, e.g., 200 nm, as a condition for the ion implantation, the acceleration voltage is, e.g., 500 keV. The dose can be an amount which can amorphize the Ni film 66, e.g., 1×10¹⁴-1×10¹⁵ cm⁻².

Then, on the amorphized Ni film 66, a protection film 68 of, e.g., a 5-50 nm-thickness TiN film by, e.g., PVD (see FIG. 23C). The protection film 68 is for preventing the oxidation of the nickel film 66, and a nickel silicide film to be formed. The protection 68 is not limited to titanium nitride film. The protection film 68 can be, e.g., a 5-30 nm-thickness Ti film.

The steps following the formation of the protection film 68 are the same as those of the method for fabricating the semiconductor device according to the first embodiment illustrated in FIGS. 16A to 18C, and their explanation will be omitted.

As described above, in the method for fabricating the semiconductor device according to the present embodiment, the Ni film 66 is amorphized by implanting Ni ions into the Ni film 66 before the first thermal processing for the silicidation. Accordingly, in the silicidation process by the first thermal processing, the Ni in the Ni film 66 reacts with Si while being diffused at higher diffusion velocity in comparison with the Ni in the Ni film 66 which is not amorphized. Thus, the Ni₂Si films 70a, 70b can be effectively formed stably by the first thermal processing, whereby the NiSi film 72a, 72b of good quality can be formed while the formation of NiSi₂ film is more effectively suppressed.

In the present embodiment, the Ni film 66 is amorphized by implanting Ni ions. However, the method for amorphizing the Ni film 66 is not essentially limited to ion implantation. The Ni film 66 may be amorphized by, e.g., depositing Ni under conditions which make the sputter rate as high as, e.g., above 1 nm/second including 1 nm/second or making the pressure of argon (Ar) for sputtering higher than, e.g., above 5 mTorr including 5 mTorr. In the case that the Ni film 66 is nano-grained by such methods, the same effect as produced by the amorphization of the Ni film 66 can be produced. Here, nano-graining means that the grain diameter of the grains forming the metal film is made the nanometer-order.

Patent Reference 1 discloses that in the salicide process using Co film, a silicon substrate is amorphized before Co film is formed on the silicon substrate for the purpose of suppressing the abnormal growth (formation of spikes) of CoSiₓ which is a cause for the junction leak current. However, the technique disclosed in Patent Reference 1 is for amorphizing the silicon substrate and is irrelevant to the method for fabricating the semiconductor device according to the present embodiment, in which the Ni film is amorphized in the salicide process using Ni film.

### A THIRD EMBODIMENT

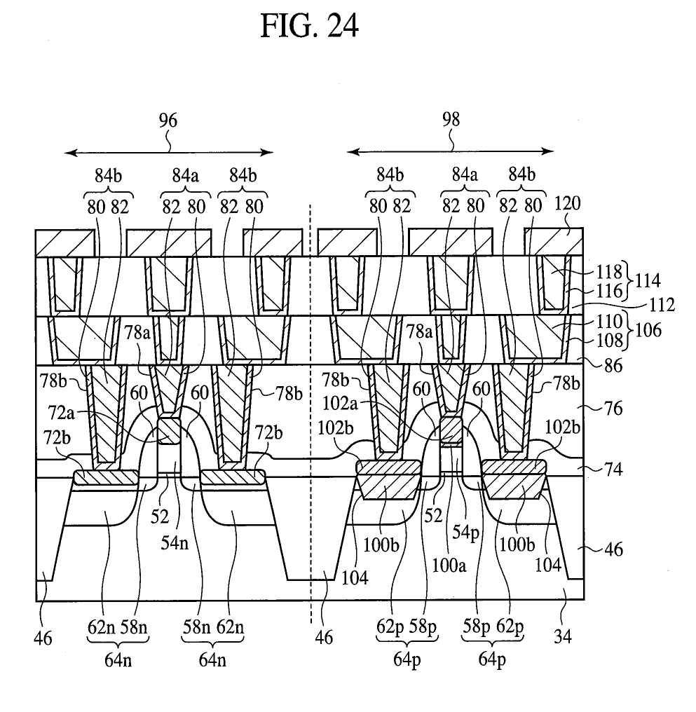

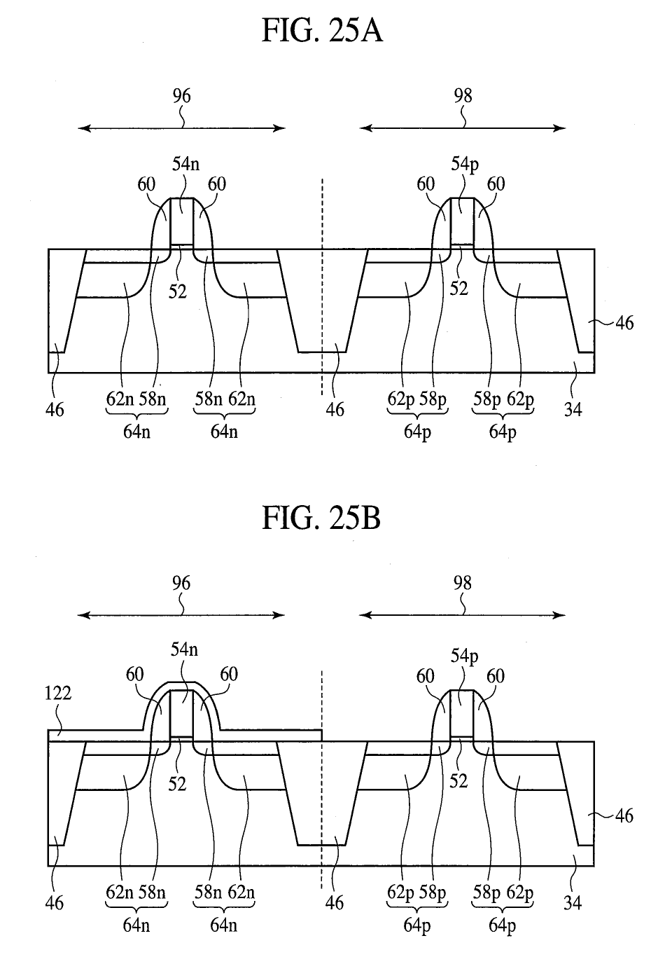

The semiconductor device and the method for fabricating the same according to a third embodiment of the present invention will be explained with reference to FIGS. 24 to 29B. FIG. 24 is a sectional view of the semiconductor device according to the present embodiment, which illustrates a structure thereof. FIGS. 25A to 29B are sectional views of the semiconductor device according to the present embodiment in the steps of the method for fabricating the same, which illustrate the method. The same members of the present embodiment as those of the semiconductor device and the method for fabricating the same according to the first embodiment illustrated in FIGS. 7 to 18C will be represented by the same reference numbers not to repeat or to simplify their explanation.

First, the structure of the semiconductor device according to the present embodiment will be explained with reference to FIG. 24.

Device isolation regions 46 for defining device regions are formed in a silicon substrate 34. The device region on the left side of the drawing is an NMOS transistor formed region 96, and the device region on the right side of the drawing is a PMOS transistor formed region 98. A p type well (not illustrated) is formed in the silicon substrate 34 of the NMOS transistor formed region 96. An n type well (not illustrated) is formed in the silicon substrate 34 in the PMOS transistor formed region 98.

On the silicon substrate 34 in the NMOS transistor formed region 96, a gate electrode 54n of polysilicon film is formed with a gate insulation film 52 of silicon oxide film formed therebetween. On the gate electrode 54n, a nickel silicide film 72a of NiSi alone is formed. That is, the nickel silicide film 72a is formed of only nickel silicide of NiSi phase alone. The film thickness of the nickel silicide film 72a is, e.g., below 20 nm including 20 nm.

A sidewall insulation film 60 is formed on the side wall of the gate electrode 54n with the nickel silicide film 72a formed on.

In the silicon substrate 34 on both sides of the gate electrode 54n, source/drain diffused layers 64n formed of a shallow impurity diffused region 58n forming the extension region of the extension source/drain structure and a deep impurity diffused region 62n are formed. On the source/drain diffused layers 64n, nickel silicide films 72b of NiSi alone are formed. That is, the nickel silicide film 72b is formed of only nickel silicide of NiSi phase alone. The film thickness of the nickel silicide film 72b is, e.g., below 20 nm including 20 nm.

Thus, the NMOS transistor including the gate electrode 54n and the source/drain diffused layers 64n is formed on the silicon substrate 34 in the NMOS transistor formed region 96.

On the silicon substrate 34 in the PMOS transistor formed region 98, a gate electrode 54p of the polysilicon film is formed with a gate insulation film 52 of silicon oxide film. The gate electrode 54p further includes an Si₁₋ₓGeₓ film 100a whose composition ratio x is 0<x<1 on the polysilicon film. The composition of the Si₁₋ₓGeₓ film 100a is, e.g., Si_{0.76}Ge_{0.24}. On the Si₁₋ₓGeₓ film 100a of the gate electrode 54p, a nickel silicide film 102a of NiSi₁₋ₓGeₓ alone whose composition ratio x is 0<x<1 is formed. That is, nickel silicide film 102a is formed of only nickel silicide of NiSi₁₋ₓGeₓ phase alone whose composition ratio x is 0<x<1. The composition ratio between the Ni and the Si₁₋ₓGeₓ of the NiSi₁₋ₓGeₓ of the nickel silicide film 102a is 1:1. Specifically, the composition ratio of the nickel silicide film 102a is, e.g., NiSi_{0.76}Ge_{0.24}. The film thickness of the nickel silicide film 102a is, e.g., below 20 nm including 20 nm.

A sidewall insulation film 60 is formed on the side wall of the gate electrode 54p with the nickel silicide film 102a formed on.

In the silicon substrate 34 on both sides of the gate electrode 54p, source/drain diffused layers 64p formed of a shallow impurity diffused region 58p forming the extension region of the extension source/drain structure and a deep impurity diffused region 62p are formed.

Hollows 104 are formed in the source/drain diffused layers 64p on both sides of the gate electrode 54p and the sidewall insulation film 60. In the hollows 104, Si₁₋ₓGeₓ films 100b whose composition ratio x is 0<x<1 are buried. The composition of the Si₁₋ₓGeₓ film 100b is the same as that of the Si₁₋ₓGeₓ film 100a and is, e.g., Si_{0.76}Ge_{0.24}. As described above, the PMOS transistor of the semiconductor device according to the present embodiment has the Si₁₋ₓGeₓ films 100b buried in the source/drain regions. Because of the lattice constant of Si₁₋ₓGeₓ larger than that of Si, a compressive strain is exerted to the part of the silicon substrate 34, which is to be the channel layer. Thus, high hole mobility can be realized.

On the Si₁₋ₓGeₓ films 100b buried in the hollows 104 in the source/drain diffused layers 64p, nickel silicide films 102b of NiSi₁₋ₓGeₓ alone whose composition ratio x is 0<x<1 are formed. That is, the nickel silicide film 102b is formed of only nickel silicide of NiSi₁₋ₓGeₓ phase alone whose composition ratio x is 0<x<1. The composition ratio of the Ni and Si₁₋ₓGeₓ of NiSi₁₋ₓGeₓ of the nickel silicide film 102b is 1:1. Specifically, the composition of the nickel silicide film 102b is the same as the composition of the nickel silicide film 102a, e.g., NiSi_{0.76}Ge_{0.24}. The film thickness of the nickel silicide film 102b is, e.g., below 20 nm including 20 nm.

Thus, the PMOS transistor including the gate electrode 54p and the source/drain diffused layers 64p is formed on the silicon substrate 34 in the PMOS transistor formed region 98.

On the silicon substrate 34 with the NMOS transistor and the PMOS transistor formed on, a silicon nitride film 74 is formed. On the silicon nitride film 74, a silicon oxide film 76 is formed.

In the silicon oxide film 76 and the silicon nitride film 74, contact holes 78a are formed down to the nickel silicide film 72a, 102a on the gate electrodes 54n, 54p. In the silicon oxide film 76 and the silicon nitride film 74, contact holes 78b are formed down to the nickel silicide films 72b, 102b on the source/drain diffused layers 64n, 64p.

Contact plugs 84a, 84b of a barrier metal 80 and a tungsten film 82 are buried respectively in the contact holes 78a, 78b.

On the silicon oxide film 76 with the contact plugs 84a, 84b buried in, an inter-layer insulation film 86 is formed. In the inter-layer insulation film 86, interconnection layers 106 are buried, electrically connected to the contact plugs 84a, 84b. The interconnection layer 106 is formed of a barrier metal 108 of tantalum film and a copper film 110.

On the inter-layer insulation film 86 with the interconnection layers 106 buried in, an inter-layer insulation film 112 is formed. In the inter-layer insulation film 112, interconnection layers 114 are buried, electrically connected to the interconnection layers 106. The interconnection layer 114 is formed of a barrier metal 116 of tantalum film and a copper film 118.

On the inter-layer insulation film 112 with the interconnection layers 114 buried in, electrodes 120 are formed, electrically connected to the interconnection layers 114. The electrodes 120 are formed of aluminum film.

Thus, the semiconductor device according to the present embodiment is constituted.

The semiconductor device according to the present embodiment is characterized mainly in that in the PMOS transistor in which compressive strain is exerted by the Si₁₋ₓGeₓ films 100b to the part of the silicon substrate 34, which is to be the channel layer, the nickel silicide films 102a, 102b formed respectively on the Si₁₋ₓGeₓ film 100a of the gate electrode 64p and on the Si₁₋ₓGeₓ films 100b buried in the hollows 104 of the source/drain diffused layers 64p are formed of only nickel silicide of NiSi₁₋ₓGeₓ phase alone whose composition ratio x is 0<x<1.

That is, in the semiconductor device according to the present embodiment, no Ni(Si₁₋ₓGeₓ)₂ crystals are formed in the nickel silicide films 102a, 102b. No Ni(Si₁₋ₓGeₓ)₂ crystals are formed either in the interface between the nickel silicide film 102a and the Si₁₋ₓGeₓ film 100a of the gate electrode 54p. No Ni(Si₁₋ₓGeₓ)₂ crystals are formed either in the interfaces between the nickel silicide films 102b and the Si₁₋ₓGeₓ films 100b buried in the hollows 104 of the source/drain diffused layers 64p. Here, the Ni(Si₁₋ₓGeₓ)₂ crystals mean mixed crystals whose composition ratio between Ni and Si₁₋ₓGeₓ is 1:2. Ni(Si₁₋ₓGeₓ)₂ crystals have higher resistance in comparison with NiSi₁₋ₓGeₓ crystals whose composition ratio between Ni and Si₁₋ₓGeₓ is 1:1 and is a cause for the scatter of the sheet resistance and the junction leak current increase, as are the NiSi₂ crystals.

As described above, the nickel silicide film 102a is formed of only nickel silicide of NiSi₁₋ₓGeₓ phase alone, whereby the roughness in the interface between the NiSi₁₋ₓ Geₓ film 102a and the Si₁₋ₓGeₓ film 100a of the gate electrode 54p can be made small, and the scatter of the sheet resistance of the surface of the Si₁₋ₓGeₓ film 100a of the gate electrode 54p can be suppressed. The nickel silicide films 102b are formed of only nickel silicide of NiSi₁₋ₓGeₓ phase alone, whereby the roughness in the interfaces between the NiSi₁₋ₓGeₓ films 102b and the Si₁₋ₓGeₓ films 100b buried in the hollows 104 of the source/drain diffused layers 64p can be made small, and the scatter of the sheet resistance of the surfaces of the Si₁₋ₓGeₓ films 100b buried in the hollows 104 of the source/drain diffused layers 64p can be suppressed.

The film thickness of the nickel silicide film 102b is as thin as, e.g., below 20 nm including 20 nm, and besides, the Ni(Si₁₋ₓGeₓ)₂ crystals, which are a cause for generating the junction leakage, are not formed down to the vicinity of the junctions of the source/drain diffused layers 64p, whereby the junction leak current can be suppressed even when the junction depths of the source/drain diffused layers 64p are shallow.

According to the present embodiment, the Si₁₋ₓGeₓ films 100b buried in the source/drain regions of the PMOS transistor exert compressive strain to the channel layer of the PMOS transistor, whereby the operation speed of the PMOS transistor can be increased.

Next, the method for fabricating the semiconductor device according to the present embodiment will be explained with reference to FIGS. 25A to 29B.

In the same way as in the method for fabricating the semiconductor device according to the first embodiment illustrated in FIGS. 8A to 15A, the NMOS transistor and the PMOS transistor are formed in the NMOS transistor-to-be-formed region 96 and the PMOS transistor-to-be-formed region 98 up to the impurity diffused layers 64n, 64p (see FIG. 25A).

Next, on the entire surface, a silicon oxide film 122 of, e.g., a 40 nm-thickness is formed by, e.g., CVD.

Next, the silicon oxide film 122 is patterned by photolithography and dry etching. Thus, the silicon oxide film 122 on the PMOS transistor-to-be-formed region 98 and the device isolation region 46 defining the PMOS transistor-to-be-formed region 98 is removed and the silicon oxide film 122 is left selectively on the NMOS transistor-to-be-formed region 96 and the device isolation region 46 defining the NMOS transistor-to-be-formed region 96 (see FIG. 25B).

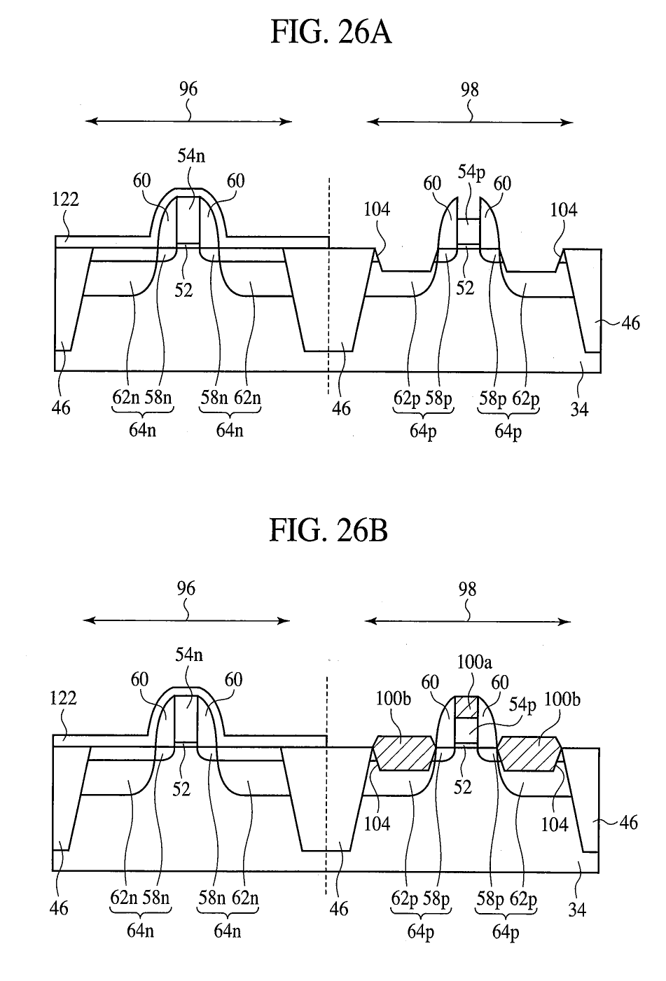

Then, with the silicon oxide film 122 as the mask, the silicon substrate 34 is etched by, e.g., RIE with a high selectivity ratio to the silicon oxide film. Thus, the hollows 104 of a 50 nm-depth are formed in the source/drain diffused layers 64p on both sides of the gate electrode 54p and the sidewall insulation film 60. At this time, the upper part of the gate electrode 54p of polysilicon film is etched off (see FIG. 26A).

Next, the Si surface is cleaned for 5 seconds with diluted hydrofluoric acid (e.g., HF:H₂O=5:100), and with the silicon oxide film 122 as the mask, the Si₁₋ₓGeₓ films 100a, 100b of, e.g., a 60 nm-thickness are epitaxially grown by, e.g., CVD selectively on the gate electrode 54p and in the hollows 104 (see FIG. 26B). The compositions of the Si₁₋ₓGeₓ films 100a, 100b are, e.g., Si_{0.76}Ge_{0.24}. As the conditions for forming the Si₁₋ₓGeₓ films 100a, 100b, for example, the raw material gas is a mixed gas of GeH₄, SiH₄ and B₂H₆, the partial pressure of the GeH₄ is 0.3 Pa, the partial pressure of the SiH₄ is 6 Pa, the partial pressure of the B₂H₆ is 0.00001 Pa, and the film forming temperature is 550° C.

Thus, in the PMOS transistor-to-be-formed region 98, the Si₁₋ₓGeₓ films 100b are buried in the hollows 104 of the source/drain diffused layers 64p. The gate electrode 54p includes the Si₁₋ₓGeₓ film 100a on the polysilicon film.

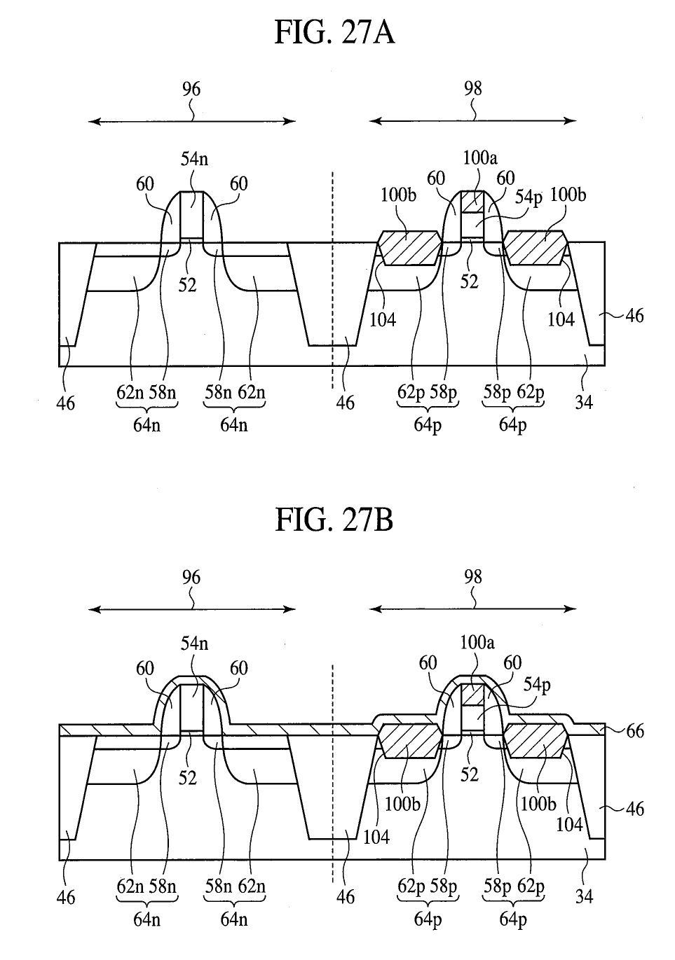

Then, the silicon oxide film 122 formed in the NMOS transistor-to-be-formed region 96 is etched off (see FIG. 27A).

Then, a natural oxide film formed on the surface of the gate electrode 54n, the surfaces of the source/drain diffused layers 64n, the surface of the Si₁₋ₓGeₓ film 100a of the gate electrode 54p and the surfaces of the Si₁₋ₓGeₓ films 100b buried in the hollows 104 of the source/drain diffused layers 64p is removed by, e.g., hydrofluoric acid processing.

Next, an Ni film 66 of, e.g., a 20 nm-thickness is formed on the entire surface by, e.g., sputtering using an Ni target (see FIG. 27B). The film thickness of the Ni film 66 is, e.g., above 17 nm including 17 nm. As will be described later, the part of the Ni film 66, which has not reacted with Si or Si₁₋ₓGeₓ, must be surely removed after the first thermal processing, and the film thickness of the Ni film 66 is preferably below 200 nm including 200 nm.

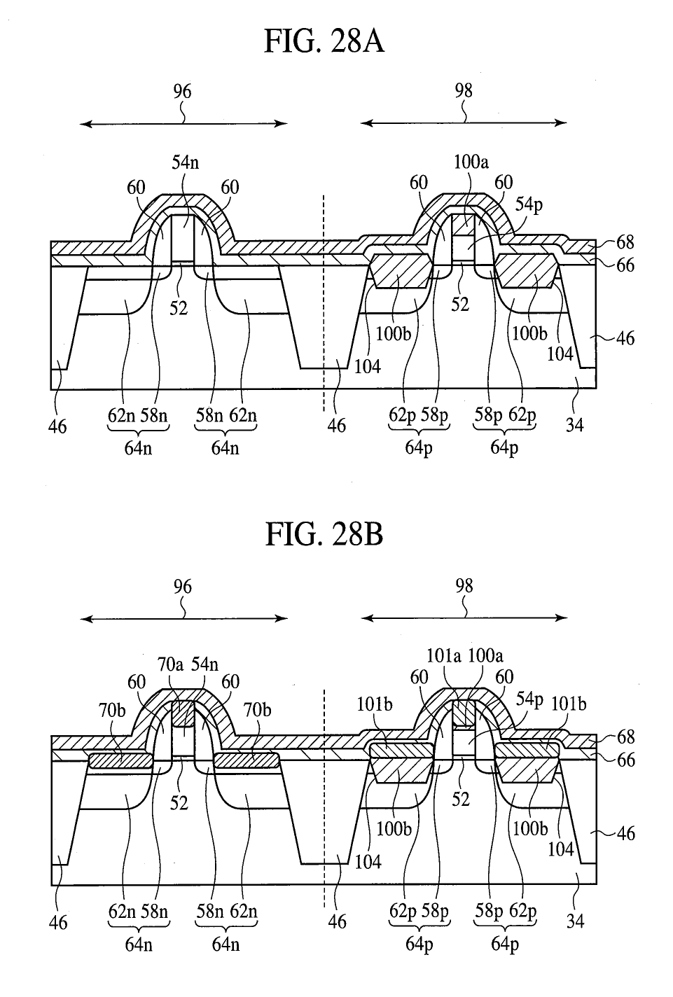

Next, on the Ni film 66, the protection film 68 of, e.g., a 10 nm-thickness TiN film is formed by, e.g., sputtering (see FIG. 28A). The protection film 68 is not limited to titanium nitride film. The protection film 68 can be, e.g., a 5-30 nm-thickness Ti film.

Next, as the first thermal processing for the silicidation, thermal processing of, e.g., 270° C. and 30 seconds is performed by, e.g., RTA.

By the first thermal processing, in the NMOS transistor, in the same way as in the method for fabricating the semiconductor device according to the first embodiment, the Ni in the lower part of the Ni film 66 and the Si in the upper part of the gate electrode 54n are reacted with each other, and the Ni in the lower part of the Ni film 66 and the Si in the upper parts of the source/drain diffused layers 64n are reacted with each other. Thus, the Ni₂Si film 70a is formed on the gate electrode 54n, and the Ni₂Si films 70b are formed on the source/drain diffused layers 64n (see FIG. 28B). That is, the nickel silicide films 70a, 70b formed of only nickel silicide of Ni₂Si phase alone are formed in the interface between the gate electrode 54n and the Ni film 66 and in the interfaces between the source/drain diffused layers 64n and the Ni film 66.

By the first thermal processing, in the PMOS transistor, the Ni in the lower part of the Ni film 66 and the Si₁₋ₓGeₓ in the upper part of the Si₁₋ₓGeₓ film 100a are reacted with each other, and the Ni in the lower part of the Ni film 66 and the Si₁₋ₓGeₓ in the upper parts of the Si₁₋ₓGeₓ films 100b buried in the hollows 104 of the source/drain diffused layers 64p are reacted with other. Thus, the Ni₂Si₁₋ₓGeₓ film 101a is formed on the Si₁₋ₓGeₓ film 100a, and the Ni₂Si₁₋ₓGeₓ films 101b are formed on the Si₁₋ₓGeₓ films 100b (see FIG. 28B). That is, the nickel silicide films 101a, 101b formed of only nickel silicide of Ni₂Si₁₋ₓGeₓ phase alone are formed in the interface between the Si₁₋ₓGeₓ film 100a and the Ni film 66 and in the interfaces between the Si₁₋ₓGeₓ films 100b and the Ni film 66. The composition ratio between Ni and Si₁₋ₓGeₓ of Ni₂Si₁₋ₓGeₓ of the nickel silicide films 101a, 101b is 2:1. Specifically, the compositions of the nickel silicide films 101a, 101b are, e.g., Ni₂Si_{0.76}Ge_{0.24}.

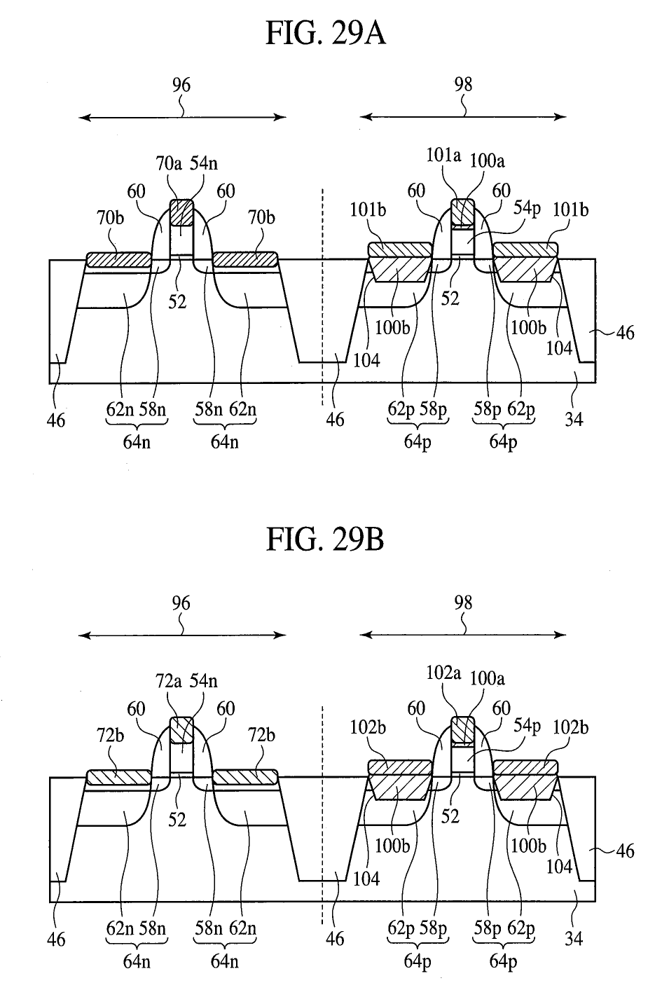

Next, the protection film 68 and the part of the Ni film 66, which have not reacted with Si or Si₁₋ₓGeₓ, are respectively selectively removed by wet etching (see FIG. 29A). The etchant is, e.g., sulfuric acid/hydrogen peroxide mixture mixing sulfuric acid and hydrogen peroxide by 3:1. The etching period of time is, e.g., 20 minutes. In place of sulfuric acid/hydrogen peroxide mixture, hydrochloric acid/hydrogen peroxide mixture mixing hydrochloric acid and hydrogen peroxide may be used.

Next, as the second thermal processing for the silicidation, thermal processing of, e.g., 400° C. and 30 seconds is performed by, e.g., RTA. The second thermal processing may be performed at 300-500° C. for 10-120 seconds.

By the second thermal processing, in the NMOS transistor, in the same way as in the method for fabricating the semiconductor device according to the first embodiment, the Ni₂Si in the Ni₂Si film 70a and the Si in the upper part of the gate electrode 54n are reacted with each other, and the Ni₂Si in the Ni₂Si films 70b and the Si in the upper parts of the source/drain diffused layers 64n are reacted with each other. Thus, the NiSi film 72a is formed on the gate electrode 54n, and the NiSi films 72b are formed on the source/drain diffused layers 64n (see FIG. 29B). That is, the nickel silicide film 72a, 72b formed of only nickel silicide of NiSi phase alone are formed on the gate electrode 54n and the source/drain diffused layers 64n.

By the second thermal processing, in the PMOS transistor, the Ni₂Si₁₋ₓGeₓ in the Ni₂Si₁₋ₓGeₓ film 101a and the Si₁₋ₓGeₓ in the upper part of the Si₁₋ₓGeₓ film 100a are reacted with each other, and the Ni₂Si₁₋ₓGeₓ in the Ni₂Si₁₋ₓGeₓ films 101b and the Si₁₋ₓGeₓ in the upper parts of the Si₁₋ₓGeₓ films 100b are reacted with each other. Thus, the NiSi₁₋ₓGeₓ film 102a is formed on the Si₁₋ₓGeₓ film 100a, and the NiSi₁₋ₓGeₓ films 102b are formed on the Si₁₋ₓGeₓ films 100b (see FIG. 29B). That is, the nickel silicide films 102a, 102b formed of NiSi₁₋ₓGeₓ alone are formed on the Si₁₋ₓGeₓ film 100a and the Si₁₋ₓGeₓ films 100b. The compositions of the nickel silicide films 102a, 102b are, e.g., NiSi_{0.76}Ge_{0.24}.

Thus, by the salicide process, in the NMOS transistor, in the same way as in the method for fabricating the semiconductor device according to the first embodiment, the NiSi film 72a is formed on the gate electrode 54n, and the NiSi films 72b are formed on the source/drain diffused layers 64n. The film thickness of the Ni film 66 and the conditions for the first and the second thermal processing are suitably set to thereby form the NiSi films 72a, 72b in a required film thickness. For example, the NiSi films 72a, 72b can be formed in a thickness of below 20 nm including 20 nm.

By the salicide process, in the PMOS transistor, the NiSi₁₋ₓGeₓ film 102a is formed on the Si₁₋ₓGeₓ film 100a of the gate electrode 54p, and the NiSi₁₋ₓGeₓ films 102b are formed on the Si₁₋ₓGeₓ films 100b buried in the hollows 104 of the source/drain diffused layers 64p. The film thickness of the Ni film 66 and the conditions for the first and the second thermal processing are suitably set to thereby form the NiSi₁₋ₓGeₓ films 102a, 102b in a required film thickness. For example, the NiSi₁₋ₓGeₓ films 102a, 102b can be formed in a thickness of below 20 nm including 20 nm.

As described above, the method for fabricating the semiconductor device according to the present embodiment is characterized mainly in that after the Ni film 66 has been formed relatively thick, first, the first thermal processing is performed to react, in the PMOS transistor, the Si₁₋ₓGeₓ in the upper parts of the Si₁₋ₓGeₓ film 100a of the gate electrode 54p and the Si₁₋ₓGeₓ films 100b buried in the hollows 104 of the source/drain diffused layers 64p and the Ni in the lower part of the Ni film 66 with each other to thereby form the Ni₂Si₁₋ₓGeₓ films 101a, 101b respectively on the Si₁₋ₓGeₓ films 100a, 100b, and after the part of the Ni film 66, which has not reacted with the Si₁₋ₓGeₓ, is selectively removed, the second thermal processing is performed to thereby react the Si₁₋ₓGeₓ in the upper parts of the Si₁₋ₓGeₓ films 100a, 100b and the Ni₂Si₁₋ₓGeₓ in the Ni₂Si₁₋ₓGeₓ films 101a, 101b with each other to form the NiSi₁₋ₓGeₓ films 102a, 102b respectively on the Si₁₋ₓGeₓ films 100a, 100b.

In the PMOS transistor, by the first thermal processing, the Si₁₋ₓGeₓ in the upper parts of the Si₁₋ₓGeₓ film 100a of the gate electrode 54p and the Si₁₋ₓGeₓ films 100b buried in the hollows 104 of the source/drain diffused layers 64p and the Ni in the lower part of the Ni film 66 formed relatively thick are reacted with each other, whereby by the first thermal processing, the Ni₂Si₁₋ₓGeₓ films 101a, 101b can be formed while the formation of the Ni(Si₁₋ₓGeₓ)₂ crystals is being suppressed. Then, after the part of the Ni film 66, which has not reacted with the Si₁₋ₓGeₓ, is selectively etched off, by the second thermal processing, the Si₁₋ₓGeₓ in the upper parts of the Si₁₋ₓGeₓ films 100a, 100b and the Ni₂Si₁₋ₓGeₓ in the Ni₂Si₁₋ₓGeₓ films 101a, 101b are reacted with each other to form the NiSi₁₋ₓGeₓ films 102a, 102b, whereby the NiSi₁₋ₓGeₓ films 102a, 102b are prevented from being formed too thick. The film thickness of the NiSi₁₋ₓGeₓ films 102a, 102b can be controlled by suitably setting the conditions for the first and the second thermal processing, such as thermal processing temperature, thermal processing period time, etc.

Thus, the NiSi₁₋ₓGeₓ films 102a, 102b of good quality can be formed in a required film thickness on the Si₁₋ₓGeₓ film 100a of the gate electrode 54p and the Si₁₋ₓGeₓ films 100b buried in the hollows 104 of the source/drain diffused layers 64p while the formation of Ni(Si₁₋ₓGeₓ)₂ crystals of high resistance is being suppressed. Thus, the roughness in the interface between the NiSi₁₋ₓGeₓ film 102a and the Si₁₋ₓGeₓ film 100a of the gate electrode 54p can be made small, and the scatter of the sheet resistance of the surface of the Si₁₋ₓGeₓ film 100a of the gate electrode 54p can be suppressed. Also the roughness in the interfaces between the NiSi₁₋ₓGeₓ films 102b and the Si₁₋ₓGeₓ films 100b buried in the hollows 104 of the source/drain diffused layers 64p can be made small, and the scatter of the sheet resistances of the surfaces of the Si₁₋ₓGeₓ films 100b buried in the hollows 104 of the source/drain diffused layers 64p can be suppressed. The junction leak current can be suppressed.

Then, after the contact plugs 85a, 84b, etc. have been formed in the same way as in the method for fabricating the semiconductor device according to the first embodiment illustrated in FIGS. 17A to 18C, the interconnection layers 106, 114, the electrodes 120, etc. are formed by the usual interconnection and electrode forming processes. The process following the salicide process is made at a temperature of, e.g., below 500° C. including 500° C. so as to suppress the agglomeration of the NiSi film 72a, 72b, and the NiSi₁₋ₓGeₓ films 102a, 102b.

Thus, the semiconductor device according to the present embodiment illustrated in FIG. 24 is fabricated.

In the method for fabricating the semiconductor device described above, the steps from the step of forming the Ni film 66 to the step of performing the first thermal processing may be performed continuously without the exposure to the atmospheric air, as in the method for fabricating the semiconductor device according to the modification of the first embodiment.

In the method for fabricating the semiconductor device described above, before the first thermal processing for the silicidation, the Ni film 66 may be amorphized by implanting Ni ions as in the method for fabricating the semiconductor device according to the second embodiment.

### A FOURTH EMBODIMENT

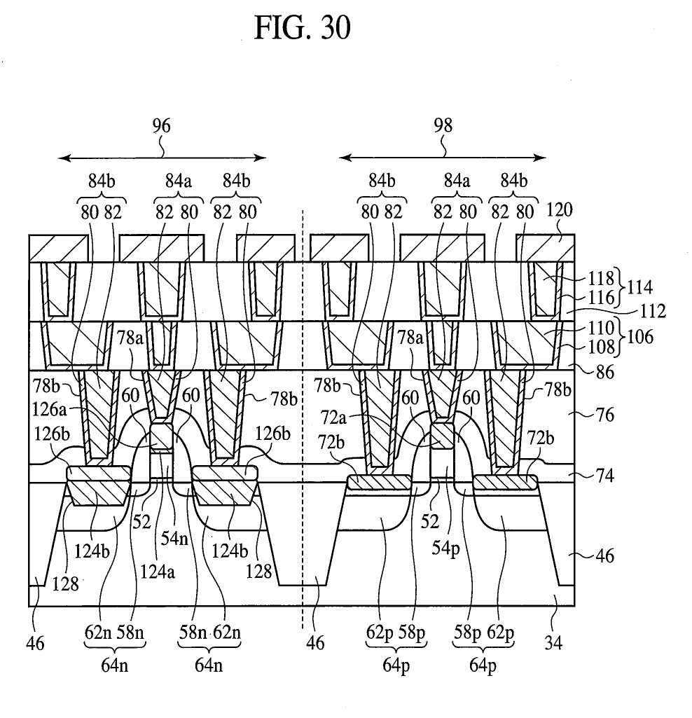

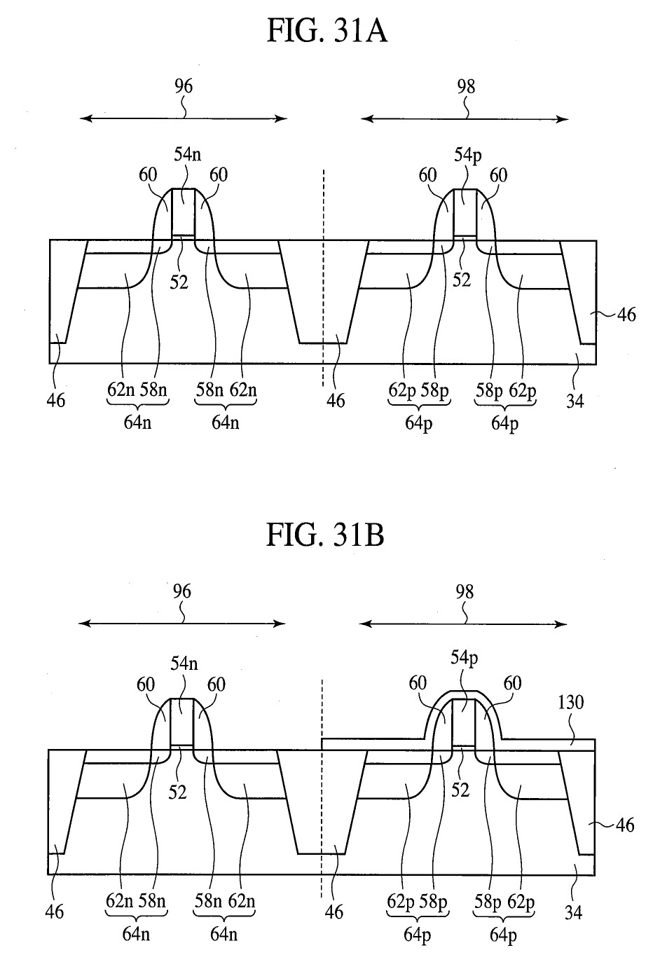

The semiconductor device and the method for fabricating the same according to a fourth embodiment of the present invention will be explained with reference to FIGS. 30 to 35B. FIG. 30 is a sectional view of the semiconductor device according to the present embodiment, which illustrates a structure thereof. FIGS. 31A to 35B are sectional views of the semiconductor device according to the present embodiment in the steps of the method for fabricating the same, which illustrate the method. The same members of the present embodiment as those of the semiconductor device and the method for fabricating the same according to the third embodiment illustrated in FIGS. 24 to 29B are represented by the same reference numbers not to repeat or to simplify their explanation.

First, the structure of the semiconductor device according to the present embodiment will be explained with reference to FIG. 30.

Device insulation regions 46 for defining an NMOS transistor formed region 96 and a PMOS transistor formed region 98 are formed in a silicon substrate 34 as in the semiconductor device according to the third embodiment.

On the silicon substrate 34 in the NMOS transistor formed region 96, a gate electrode 54n of polysilicon film is formed with a gate insulation film 52 of silicon oxide film formed therebetween. The gate electrode 54n further includes an Si_{1-x-y}GeₓC_{y} film 124a whose composition ratios x, y satisfy 0<x<1, 0<y<0.01 and 1−x−y>0 on the polysilicon film. The lattice constant of the Si_{1-x-y}GeₓC_{y} of the Si_{1-x-y}GeₓC_{y} film 124a is set smaller than the lattice constant of Si. The composition of the Si_{1-x-y}GeₓC_{y} film 124a is, e.g., Si_{0.98}Ge_{0.011}C_{0.009}. On the Si_{1-x-y}GeₓC_{y} film 124a of the gate electrode 54n, a nickel silicide film 126a formed of NiSi_{1-x-y}GeₓC_{y} alone whose composition ratios x, y satisfy 0<x<1, 0<y<0.01 and 1−x−y>0 is formed. That is, the nickel silicide film 126a is formed of only nickel silicide of Si_{1-x-y}GeₓC_{y} phase alone whose composition ratios x, y satisfy 0<x<1, 0<y<0.01 and 1−x−y>0. The composition ratio between the Ni and the Si_{1-x-y}GeₓC_{y} of the NiSi_{1-x-y}GeₓC_{y} of the nickel silicide film 126a is 1:1. Specifically, the composition of the nickel silicide film 126a is NiSi_{0.98}Ge_{0.011}C_{0.009}. The film thickness of the nickel silicide film 126a is, e.g., below 20 nm including 20 nm.

A sidewall insulation film 60 is formed on the side wall of the gate electrode 54n with the nickel silicide film 126a formed on.

In the silicon substrate 34 on both sides of the gate electrode 54n, source/drain diffused layers 64n formed of a shallow impurity diffused region 58n forming the extension region of the extension source/drain structure and a deep impurity diffused region 62n are formed.

Hollows 128 are formed in the source/drain diffused layers 64n on both sides of the gate electrode 54n and the sidewall insulation film 60. In the hollows 128, Si_{1-x-y}GeₓC_{y} films 124b whose composition ratios x, y satisfy 0<x<1, 0<y<0.01, 1−x−y>0 are buried. The lattice constant of the Si_{1-x-y}GeₓC_{y} of the Si_{1-x-y}GeₓC_{y} film 124b is set smaller than the lattice constant of Si. The composition of the Si_{1-x-y}GeₓC_{y} film 124b is the same as that of the Si_{1-x-y}GeₓC_{y} film 124a, e.g., Si_{0.98}Ge_{0.011}C_{0.009}. As described above, the NMOS transistor of the semiconductor device according to the present embodiment has the Si_{1-x-y}GeₓC_{y} films 124b buried in the source/drain regions. Because of the lattice constant of the Si_{1-x-y}GeₓC_{y} of the Si_{1-x-y}GeₓC_{y} film 124b set smaller than the lattice constant of Si, tensile strain is exerted to the part of the silicon substrate 34, which is to be the channel layer. Thus, high electron mobility can be realized.

On the Si_{1-x-y}GeₓC_{y} films 124b buried in the hollows 128 of the source/drain diffused layers 64n, nickel silicide films 126b of NiSi_{1-x-y}GeₓC_{y} alone whose composition ratios x, y satisfy 0<x<1, 0<y<0.01 and 1−x−y>0 are formed. That is, the nickel silicide film 126b is formed of only nickel silicide of NiSi_{1-x-y}GeₓC_{y} phase alone whose composition ratios x, y satisfy 0<x<1, 0<y<0.01 and 1−x−y>0. The composition ratio between the Ni and the Si_{1-x-y}GeₓC_{y} of the NiSi_{1-x-y}GeₓC_{y} of the nickel silicide film 126b is 1:1. Specifically, the composition of the nickel silicide film 126b is the same as the composition of the nickel silicide film 126a, e.g., NiSi_{0.98}Ge_{0.011}C_{0.009}. The film thickness of the nickel silicide film 126b is, e.g., below 20 nm including 20 nm.

Thus, the NMOS transistor including the gate electrode 54n and the source/drain diffused layer 64n is formed on the silicon substrate 34 in the NOMS transistor formed region 96.

On the silicon substrate 34 in the PMOS transistor formed region 98, a gate electrode 54p of polysilicon film is formed with a gate insulation film 52 of silicon oxide film formed therebetween. On the gate electrode 54p, a nickel silicide film 72a of NiSi alone is formed. That is, the nickel silicide film 72a is formed of only nickel silicide of NiSi phase alone. The film thickness of the nickel silicide film 72a is, e.g., below 20 nm including 20 nm.

A sidewall insulation film 60 is formed on the side wall of the gate electrode 54p with the nickel silicide film 72a formed on.

In the silicon substrate 34 on both sides of the gate electrode 54p, source/drain diffused layers 64p formed of a shallow impurity diffused region 58p forming the extension region of the extension source/drain structure and a deep impurity diffused region 62p are formed. On the source/drain diffused layers 64p, nickel silicide films 72b of NiSi alone are formed. That is, the nickel silicide film 72b is formed of only nickel silicide of NiSi phase alone. The film thickness of the nickel silicide film 72b is, e.g., below 20 nm including 20 nm.

Thus, the PMOS transistor including the gate electrode 54p and the source/drain diffused layers 64p is formed on the silicon substrate 34 in the PMOS transistor formed region 98.

On the silicon substrate 34 with the NMOS transistor and the PMOS transistor formed on, a silicon nitride film 74 is formed. On the silicon nitride film 74, a silicon oxide film 76 is formed.

In the silicon oxide film 76 and the silicon nitride film 74, contact holes 78a are formed down to the nickel silicide film 126a, 72a on the gate electrodes 54n, 54p. In the silicon oxide film 76 and the silicon nitride film 74, contact holes 78b are formed down to the nickel silicide films 126b, 78b on the source/drain diffused layers 64n, 64p.

Contact plugs 84a, 84b of a barrier metal 80 and a tungsten film 82 are buried respectively in the contact holes 78a, 78b.

On the silicon oxide film 76 with the contact plugs 84a, 84b buried in, interconnection layers 106, 114, electrodes 120, etc. are formed, as in the semiconductor device according to the third embodiment.

Thus, the semiconductor device according to the present embodiment is constituted.

The semiconductor device according to the present embodiment is characterized mainly in that in the NMOS transistor in which tensile strain is exerted by the Si_{1-x-y}GeₓC_{y} films 124b to the part of the silicon substrate 34, which is to be the channel layer, the nickel silicide films 126a, 126b formed respectively on the Si_{1-x-y}GeₓC_{y} film 124a of the gate electrode 54n and on the Si_{1-x-y}GeₓC_{y} films 124b buried in the hollows 128 of the source/drain diffused layers 64n are formed of only nickel silicide of NiSi_{1-x-y}GeₓC_{y} phase alone whose composition ratios x, y satisfy 0<x<1, 0<y<0.01 and 1−x−y>0.

That is, in the semiconductor device according to the present embodiment, no Ni(Si_{1-x-y}GeₓC_{y})₂ crystals are formed in the nickel silicide film 126a, 126b. No Ni(Si_{1-x-y}GeₓC_{y})₂ crystals are formed either in the interface between the nickel silicide film 126a and the Si_{1-x-y}GeₓC_{y} film 124a of the gate electrode 54n. No Ni(Si_{1-x-y}GeₓC_{y})₂ crystals are formed either in the interfaces between the nickel silicide films 126b and the Si_{1-x-y}GeₓC_{y} films 124b buried in the hollows 128 of the source/drain diffused layers 64n. Here, the Ni(Si_{1-x-y}GeₓC_{y})₂ crystals mean the mix crystals whose composition ratio between Ni and Si_{1-x-y}GeₓC_{y} is 1:2. The Ni(Si_{1-x-y}GeₓC_{y})₂ crystals have higher resistance in comparison with the NiSi_{1-x-y}GeₓC_{y} crystals whose composition ratio between Ni and Si_{1-x-y}GeₓC_{y} is 1:1 and is a cause for the scatter of the sheet resistance and the junction leak current increase, as are the NiSi₂ crystals.

As described above, the nickel silicide film 126a is formed of only nickel silicide of NiSi_{1-x-y}GeₓC_{y} phase alone, whereby the roughness in the interface between the Si_{1-x-y}GeₓC_{y} film 126a and the Si_{1-x-y}GeₓC_{y} film 124a of the gate electrode 54n can be made small, and the scatter of the sheet resistance of the surface of the Si_{1-x-y}GeₓC_{y} film 124a of the gate electrode 54n can be suppressed. The nickel silicide films 126b are formed of only nickel silicide of NiSi_{1-x-y}GeₓC_{y} phase alone, whereby the roughness in the interfaces between the NiSi_{1-x-y}GeₓC_{y} films 126b and the Si_{1-x-y}GeₓC_{y} films 124b buried in the hollows 128 of the source/drain diffused layers 64n can be made small, and the scatter of the sheet resistance of the surfaces of the Si_{1-x-y}GeₓC_{y} films 124b buried in the hollows 128 of the source/drain diffused layers 64n can be suppressed.

The film thickness of the nickel silicide film 126b is as thin as, e.g., below 20 nm including 20 nm, and besides, the Ni(Si_{1-x-y}GeₓC_{y})₂ crystals, which are a cause for generating the junction leak current, are not formed down to the vicinity of the junctions of the source/drain diffused layers 64n, whereby the junction leak current can be suppressed even when the junction depths of the source/drain diffused layers 64n are shallow.

According to the present embodiment, the Si_{1-x-y}GeₓC_{y} films 124b buried in the source/drain diffused regions of the NMOS transistor exert tensile strain to the channel layer of the NMOS transistor, whereby the operation speed of the NMOS transistor can be increased.

Next, the method for fabricating the semiconductor device according to the present embodiment will be explained with reference to FIGS. 31A to 35B.

In the same way as in the method for fabricating the semiconductor device according to the first embodiment illustrated in FIGS. 8A to 15A, the NMOS transistor and the PMOS transistor are formed in the NMOS transistor-to-be-formed region 96 and the PMOS transistor-to-be-formed region 98 up to the impurity diffused layers 64n, 64p (see FIG. 31A).

Next, on the entire surface, a silicon oxide film 130 of, e.g., a 40 nm-thickness is formed by, e.g., CVD.

Next, the silicon oxide film 130 is patterned by photolithography and dry etching. Thus, the silicon oxide film 130 on the NMOS transistor-to-be-formed region 96 and the device isolation region 46 defining the NMOS transistor-to-be-formed region 96 is removed and the silicon oxide film 130 is left selectively on the PMOS transistor-to-be-formed region 98 and the device isolation region 46 defining the PMOS transistor-to-be-formed region 98 (see FIG. 31B).

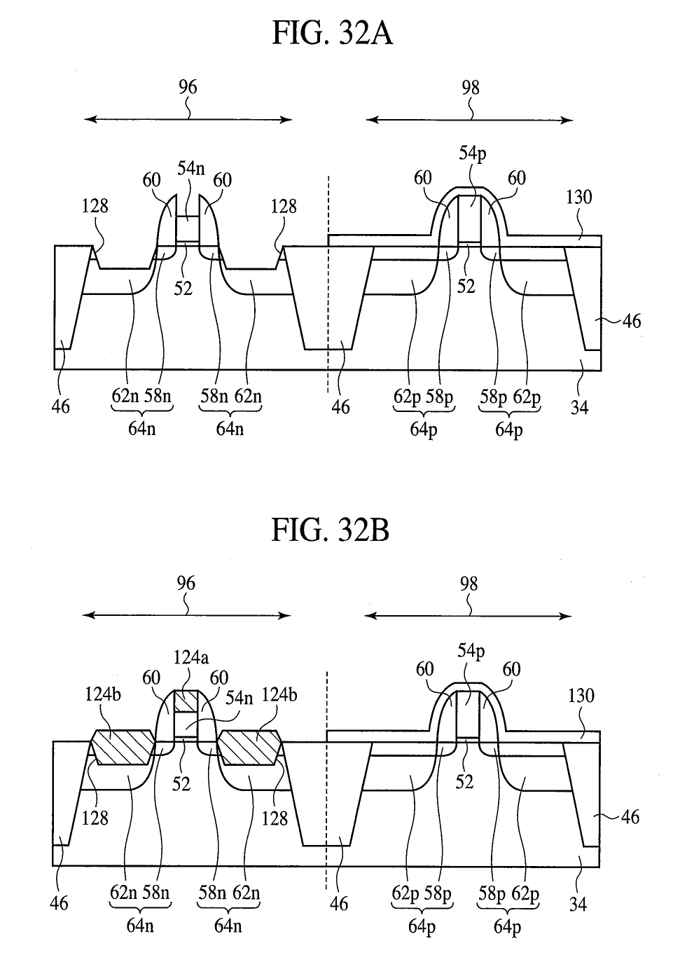

Then, with the silicon oxide film 122 as the mask, the silicon substrate 34 is etched by, e.g., RIE with a high selectivity ratio to the silicon oxide film. Thus, the hollows 128 of a 50 nm-depth are formed in the source/drain diffused layers 64n on both sides of the gate electrode 54n and the sidewall insulation film 60. At this time, the upper part of the gate electrode 54n of polysilicon film is etched off (see FIG. 32A).

Then, with the silicon oxide film 130 as the mask, an Si_{1-x-y}GeₓC_{y} film 124a, 124b of, e.g., a 60 nm-thickness is epitaxially grown by, e.g., CVD selectively on the gate electrode 54n and in the hollows 128 (see FIG. 32A). The compositions of the Si_{1-x-y}GeₓC_{y} films 124a, 124b are, e.g., Si_{0.98}Ge_{0.011}C_{0.009}. As the conditions for forming the Si_{1-x-y}GeₓC_{y} films 124a, 124b, for example, the raw material gas is a mixed gas of SiH₃CH₃, GeH₄, SiH₄ and PH₃, the partial pressure of the SiH₃CH₃ is 1 Pa, the partial pressure of the GeH₄ is 0.02 Pa, the partial pressure of the SiH4 is 6 Pa and the partial pressure of the PH₃ is 0.001 Pa, and the film forming temperature is 550° C.

Thus, in the NMOS transistor-to-be-formed region 96, the Si_{1-x-y}GeₓC_{y} films 124b are buried in the hollows 128 of the source/drain diffused layers 64n. The gate electrode 54n includes the Si_{1-x-y}GeₓC_{y} film 124a on the polysilicon film (FIG. 32B).

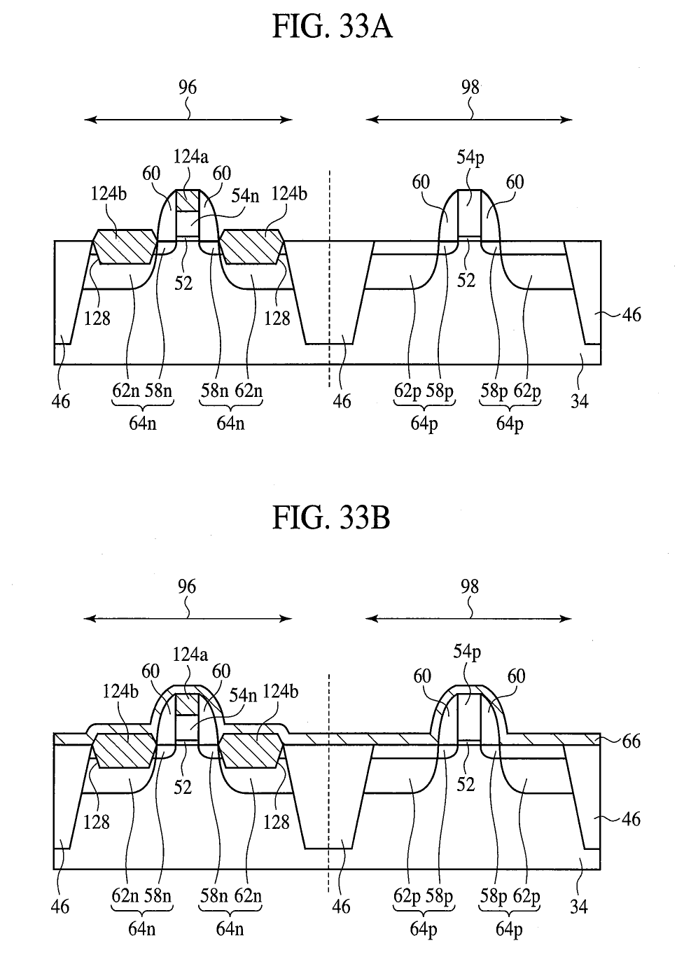

Then, the silicon oxide film 130 formed in the PMOS transistor-to-be-formed region 98 is etched off (see FIG. 33A).

Then, a natural oxide film formed on the surface of the Si_{1-x-y}GeₓC_{y} film 124a of the gate electrode 54n, the surfaces of the Si_{1-x-y}GeₓC_{y} films 124b buried in the hollows 128 of the source/drain diffused layers 64n, the surface of the gate electrode 54p and the surfaces of the source/drain diffused layers 64p is removed by hydrofluoric acid processing.

Next, an Ni film 66 of, e.g., a 20 nm-thickness is formed on the entire surface by, e.g., sputtering using an Ni target (see FIG. 33B). The film thickness of the Ni film 66 is, e.g., above 17 nm including 17 nm. As will be described later, the part of the Ni film 66, which has not reacted with Si or Si_{1-x-y}GeₓC_{y}, must be surely removed after the first thermal processing, and the film thickness of the Ni film 66 is preferably below 200 nm including 200 nm.

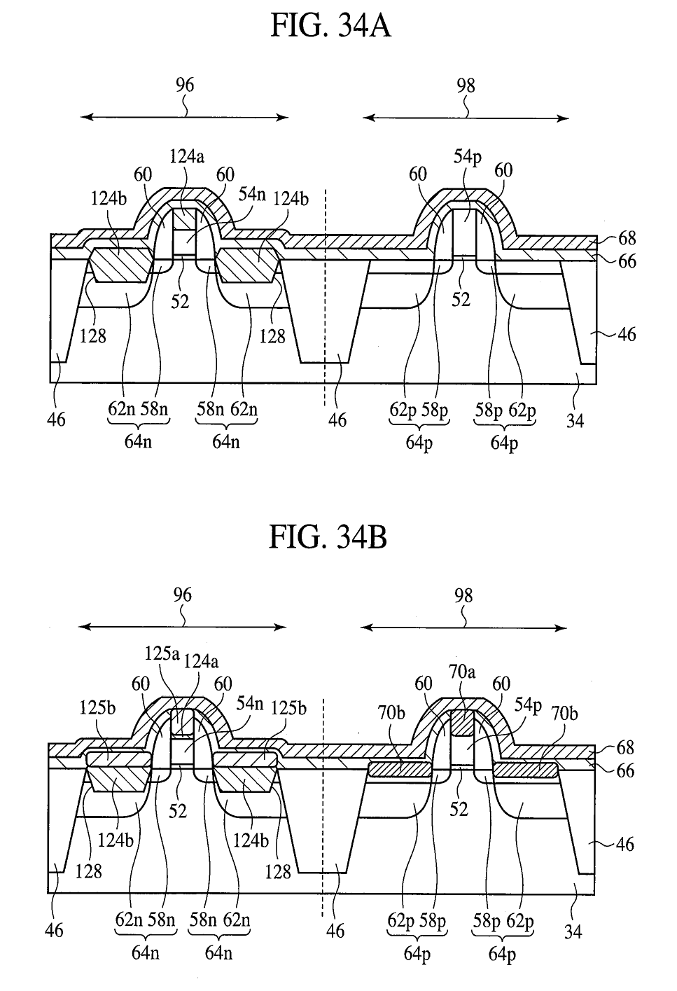

Next, on the Ni film 66, the protection film 68 of, e.g., a 10 nm-thickness TiN film is formed by, e.g., sputtering (see FIG. 34A). The protection film 68 is not limited to titanium nitride film. The protection film 68 can be, e.g., a 5-30 nm-thickness Ti film.

Next, as the first thermal processing for the silicidation, thermal processing of, e.g., 270° C. and 30 seconds is performed by, e.g., RTA.

By the first thermal processing, in the NMOS transistor, the Ni in the lower part of the Ni film 66 and the Si_{1-x-y}GeₓC_{y} in the upper part of the Si_{1-x-y}GeₓC_{y} film 124a of the gate electrode 54n are reacted with each other, and the Ni in the lower part of the Ni film 66 and the Si_{1-x-y}GeₓC_{y} in the upper parts of the Si_{1-x-y}GeₓC_{y} films 124b buried in the hollows 128 of the source/drain diffused layers 64n are reacted with each other. Thus, the Ni₂Si_{1-x-y}GeₓC_{y} film 125a is formed on the Si_{1-x-y}GeₓC_{y} film 124a, and the Ni₂Si_{1-x-y}GeₓC_{y} films 125b are formed on the Si_{1-x-y}GeₓC_{y} films 124b (see FIG. 34B). That is, the nickel silicide films 125a, 125b formed of only nickel silicide of Ni₂Si_{1-x-y}GeₓC_{y} phase alone are formed in the interface between the Si_{1-x-y}GeₓC_{y} film 124a and the Ni film 66 and in the interfaces between the Si_{1-x-y}GeₓC_{y} films 124b and the Ni film 66. The composition ratio between Ni and Si_{1-x-y}GeₓC_{y} of Ni₂Si_{1-x-y}GeₓC_{y} of the nickel silicide films 125a, 125b is 2:1. Specifically, the compositions of the nickel silicide films 125a, 125b are, e.g., Ni₂Si_{0.98}Ge_{0.011}C_{0.009}.

By the first thermal processing, in the PMOS transistor, in the same way as in the method for fabricating the semiconductor device according to the first embodiment, the Ni in the lower part of the Ni film 66 and the Si in the upper part of the gate electrode 54p are reacted with each other, and the Ni in the lower part of the Ni film 66 and the Si in the upper parts of the source/drain diffused layers 64p are reacted with each other. Thus, the Ni₂Si film 70a is formed on the gate electrode 54p, and the Ni₂Si films 70b are formed on the source/drain diffused layers 64p (see FIG. 34B). That is, the nickel silicide films 70a, 70b formed of only nickel silicide of Ni₂Si phase alone are formed in the interface between the gate electrode 54p and the Ni film 66 and in the interfaces between the source/drain diffused layers 64p and the Ni film 66.

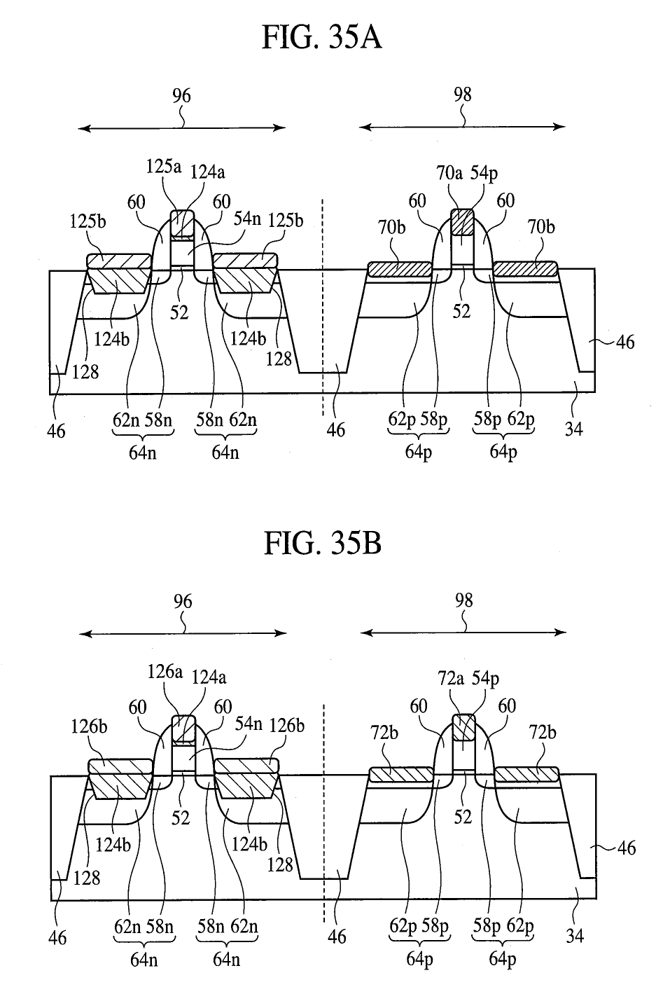

Next, the protection film 68 and the part of Ni film 66, which has not reacted with Si or Si_{1-x-y}GeₓC_{y}, are respectively selectively removed by wet etching (see FIG. 35A). The etchant is, e.g., sulfuric acid/hydrogen peroxide mixture mixing sulfuric acid and hydrogen peroxide by 3:1. The etching period of time is, e.g., 20 minutes. In place of sulfuric acid/hydrogen peroxide mixture, hydrochloric acid/hydrogen peroxide mixture mixing hydrochloric acid and hydrogen peroxide may be used.

Next, as the second thermal processing for the silicidation, thermal processing of, e.g., 400° C. and 30 seconds is performed by, e.g., RTA. The second thermal processing may be performed at 300-500° C. and 10-120 seconds.

By the second thermal processing, in the NMOS transistor, the Ni₂Si_{1-x-y}GeₓC_{y} in the Ni₂Si_{1-x-y}GeₓC_{y} film 125a and the Si_{1-x-y}GeₓC_{y} in the upper part of the Si_{1-x-y}GeₓC_{y} film 124a are reacted with each other, and the Ni₂Si_{1-x-y}GeₓC_{y} in the Ni₂Si_{1-x-y}GeₓC_{y} films 125b and the Si_{1-x-y}GeₓC_{y} in the upper parts of the Si_{1-x-y}GeₓC_{y} films 124b are reacted with each other. Thus, the NiSi_{1-x-y}GeₓC_{y} film 126a is formed on the Si_{1-x-y}GeₓC_{y} film 124a, and the NiSi_{1-x-y}GeₓC_{y} films 126b are formed on the Si_{1-x-y}GeₓC_{y} films 124b (see FIG. 35B). That is, the nickel silicide films 126a, 126b formed of NiSi_{1-x-y}GeₓC_{y} alone are formed on the Si_{1-x-y}GeₓC_{y} film 124a and the Si_{1-x-y}GeₓC_{y} films 124b. The compositions of the nickel silicide films 126a, 26b are, e.g., NiSi_{0.98}Ge_{0.011}C_{0.009}.

By the second thermal processing, in the PMOS transistor, in the same way as in the method for fabricating the semiconductor device according to the first embodiment, the Ni₂Si in the Ni₂Si film 70a and the Si in the upper part of the gate electrode 54p are reacted with each other, and the Ni₂Si in the Ni₂Si films 70b and the Si in the upper parts of the source/drain diffused layers 64p are reacted with each other. Thus, the NiSi film 72a is formed on the gate electrode 54p, and the NiSi films 72b are formed on the source/drain diffused layers 64p (see FIG. 35B). That is, the nickel silicide film 72a, 72b formed of only nickel silicide of NiSi phase alone are formed on the gate electrode 54p and the source/drain diffused layers 64p.

Thus, by the salicide process, in the NMOS transistor, the NiSi_{1-x-y}GeₓC_{y} film 126a is formed on the Si_{1-x-y}GeₓC_{y} film 124a of the gate electrode 54n, and the NiSi_{1-x-y}GeₓC_{y} films 126b are formed on the Si_{1-x-y}GeₓC_{y} films 124b buried in the hollows 128 of the source/drain diffused layers 64n. The film thickness of the Ni film 66 and the conditions for the first and the second thermal processing are suitably set to thereby form the NiSi_{1-x-y}GeₓC_{y} films 126a, 126b in a required film thickness. For example, the NiSi_{1-x-y}GeₓC_{y} films 126a, 126b can be formed in a thickness of below 20 nm including 20 nm.

By the salicide process, in the PMOS transistor, in the same way as in the method for fabricating the semiconductor device according to the first embodiment, the NiSi film 72a is formed on the gate electrode 54p, and the NiSi films 72b are formed on the source/drain diffused layers 64p. The film thickness of the Ni film 66 and the conditions for the first and the second thermal processing are suitably set to thereby form the NiSi film 72a, 72b in a required film thickness. For example, the NiSi films 72a, 72b can be formed in a thickness of below 20 nm including 20 nm.

As described above, the method for fabricating the semiconductor device according to the present embodiment is characterized in that after the Ni film 66 has been formed relatively thick, first, the first thermal processing is performed to react, in the NMOS transistor, the Si_{1-x-y}GeₓC_{y} in the upper parts of the Si_{1-x-y}GeₓC_{y} film 124a of the gate electrode 54n and the Si_{1-x-y}GeₓC_{y} films 124b buried in the hollows 128 of the source/drain diffused layers 64n and the Ni in the lower part of the Ni film 66 with each other to thereby form the Ni₂Si_{1-x-y}GeₓC_{y} films 125a, 125b respectively on the Si_{1-x-y}GeₓC_{y} films 124a, 124b, and after the part of the Ni film 66, which has not reacted with the Si_{1-x-y}GeₓC_{y}, is selectively removed, the second thermal processing is performed to thereby react the Si_{1-x-y}GeₓC_{y} in the upper parts of the Si_{1-x-y}GeₓC_{y} films 124a, 124b and the Ni₂Si_{1-x-y}GeₓC_{y} in the Ni₂Si_{1-x-y}GeₓC_{y} films 125a, 125b with each other to form the NiSi_{1-x-y}GeₓC_{y} films 126a, 126b respectively on the Si₁₋ₓGeₓC_{y} films 124a, 124b.

In the NMOS transistor, by the first thermal processing, the Si_{1-x-y}GeₓC_{y} in the upper parts of the Si_{1-x-y}GeₓC_{y} film 124a of the gate electrode 54n and the Si_{1-x-y}GeₓC_{y} films 124b buried in the hollows 128 of the source/drain diffused layers 64n and the Ni in the lower part of the Ni film 66 formed relatively thick are reacted with each other, whereby by the first thermal processing, the Ni₂Si_{1-x-y}GeₓC_{y} films 125a, 125b can be formed while the formation of the Ni(Si_{1-x-y}GeₓC_{y})₂ crystals is being suppressed. Then, after the part of the Ni film 66, which has not reacted with the Si_{1-x-y}GeₓC_{y}, is selectively etched off, by the second thermal processing, the Si_{1-x-y}GeₓC_{y} in the upper parts of the Si_{1-x-y}GeₓC_{y} films 124a, 124b and the Ni₂Si_{1-x-y}GeₓC_{y} in the Ni₂Si_{1-x-y}GeₓC_{y} films 125a, 125b are reacted with each other to form NiSi_{1-x-y}GeₓC_{y} films 126a, 126b, whereby the NiSi_{1-x-y}GeₓC_{y} films 126a, 126b are prevented from being formed too thick. The film thickness of the NiSi_{1-x-y}GeₓC_{y} films 126a, 126b can be controlled by suitably setting the conditions for the first and the second thermal processing, such as thermal processing temperature, thermal processing period of time, etc.

Thus, the NiSi_{1-x-y}GeₓC_{y} films 126a, 126b of good quality can be formed in a required film thickness on the Si_{1-x-y}GeₓC_{y} film 124a of the gate electrode 54n and the Si_{1-x-y}GeₓC_{y} films 124b buried in the hollows 128 of the source/drain diffused layers 64n while the formation of the Ni(Si_{1-x-y}GeₓC_{y})₂ crystals of high resistance is being suppressed. Thus, the roughness in the interface between the NiSi_{1-x-y}GeₓC_{y} film 126a and the Si_{1-x-y}GeₓC_{y} film 124a of the gate electrode 54n can be made small, and the scatter of the sheet resistance of the surface of the Si_{1-x-y}GeₓC_{y}film 124a of the gate electrode 54n can be suppressed. Also the roughness in the interfaces between the NiSi_{1-x-y}GeₓC_{y} films 126b and the Si_{1-x-y}GeₓC_{y} films 124b buried in the hollows 128 of the source/drain diffused layers 64n can be made small, and the scatter of the sheet resistances of the surfaces of the Si_{1-x-y}GeₓC_{y} films 124b buried in the hollows 128 of the source/drain diffused layers 64n can be suppressed. The junction leak current can be suppressed.

Then, after the contact plugs 85a, 84b, etc. have been formed in the same way as in the method for fabricating the semiconductor device according to the first embodiment illustrated in FIGS. 17A to 18C, the interconnection layers 106, 114, the electrodes 120, etc. are formed by the usual interconnection and electrode forming processes. The process following the salicide process is made at a temperature of, e.g., below 500° C. including 500° C. so as to suppress the agglomeration of the NiSi film 72a, 72b, and the NiSi_{1-x-y}GeₓC_{y} films 126a. 126b.

Thus, the semiconductor device according to the present embodiment illustrated in FIG. 30 is fabricated.

In the method for fabricating the semiconductor device described above, the steps from the step of forming the Ni film 66 to the step of performing the first thermal processing may be performed continuously without the exposure to the atmospheric air, as in the method for fabricating the semiconductor device according to the modification of the first embodiment.

In the method for fabricating the semiconductor device described above, before the first thermal processing for the silicidation, the Ni film 66 may be amorphized by implanting Ni ions, as in the method for fabricating the semiconductor device according to the second embodiment.

### MODIFIED EMBODIMENTS

The present invention is not limited to the above-described embodiments and can cover other various modifications.

For example, in the first and the second embodiments described above, the salicide process is made to form the NiSi films 72a, 72b on both of the gate electrode 54 and the source/drain diffused layers 64. However, the present invention is not limited to the case that the NiSi films 72a, 72b are formed on both the gate electrode 54 and the source/drain diffused layers 64 and is applicable to the case that the NiSi film is formed on either of the gate electrode 54 and the source/drain diffused layers 64.

In the third embodiment, the salicide process is made to form, in the PMOS transistor, the NiSi₁₋ₓGeₓ film 102a, 102b on both the gate electrode 54p and the source/drain diffused layers 64p. However, the present invention is not limited to the case that the NiSi₁₋ₓGeₓ films 102a, 102b are formed on both the gate electrode 54p and the source/drain diffused layers 64p and is applicable to the case that the NiSi₁₋ₓGeₓ film is formed on either of the gate electrode 54p and the source/drain diffused layers 64p.

In the fourth embodiment, the salicide process is made to form, in the NMOS transistor, the Si_{1-x-y}GeₓC_{y} films 126a, 126b on both the gate electrode 54n and the source/drain diffused layers 64n. However, the present invention is not limited to the case that the NiSi_{1-x-y}GeₓC_{y} films 126a, 126b are formed on both the gate electrode 54n and the source/drain diffused layers 64n and is applicable to the case that the NiSi_{1-x-y}GeₓC_{y} film is formed on either of the gate electrode 54n and the source/drain diffused layer 64n.

In the third and the fourth embodiments described above, the compressive strain or the tensile strain is exerted to the part of the silicon substrate 34, which is to be the channel layer in either of the PMOS transistor and the NMOS transistor formed on one and the same silicon substrate 34. However, in the case that an NMOS transistor and a PMOS transistor are formed on one and the same silicon substrate 34, it is possible that the compressive strain is applied to the PMOS transistor, as in the third embodiment, and the tensile strain is applied to the NMOS transistor, as in the fourth embodiment.

In the above-described embodiments, the first and the second thermal processing is performed by RTA but is not essentially performed by RTA. For example, the first and the second thermal processing may be performed by furnace annealing, spike annealing or others. RTA thermal processing, furnace annealing and spike anneal may be combined.

The conditions for the first thermal processing are not limited to those of the above-described embodiments. In the first thermal processing, the thermal processing temperature can be, e.g., 200-400° C. The thermal processing period of time can be, e.g., 10 seconds-60 minutes.

The conditions for the second thermal processing are not limited to those of the above-described embodiments. The thermal processing temperature of the second thermal processing can be substantially the same as the thermal processing temperature of the first thermal processing or higher than the latter, specifically can be, e.g., 350-650° C. The thermal processing period of time can be, e.g., 20 seconds-60 minutes. Otherwise, as the second thermal processing, spike annealing of 450-650° C. may be performed.

In the above-described embodiments, the Ni film 66 is formed by sputtering. The Ni film 66 is not formed essentially by sputtering and can be formed by vapor deposition, e.g., electron beam vapor deposition, etc.

In the above-described embodiments, the protection film 68 is formed on the Ni film 66. However, the protection film 68 is not essential. When the substrate with the Ni film formed on is loaded with the Ni film exposed in a cassette for carrying substrates, the furnace of the RTA apparatus and the chamber of the film forming apparatus, particles of the Ni often adhere to other substrates, etc. loaded later in the cassette, the furnace of the RTA apparatus and chamber of the film forming apparatus. The protection film 68 formed on the Ni film 66 can prevent such secondary contamination with the Ni.

### INDUSTRIAL APPLICABILITY

The semiconductor device and the method for fabricating the same according to the present invention can make it possible to suppress the scatter of the sheet resistance and the junction leak current of the source/drain diffused layer of a semiconductor device subjected to silicidation with nickel, and is useful to improve the operational characteristics and the yield of semiconductor devices.

1. A semiconductor device comprising:
a gate electrode formed over a semiconductor substrate;
a source/drain diffused layer formed in the semiconductor substrate on both sides of the gate electrode; and
a silicide film formed on the source/drain diffused layer,
the silicide film being formed of nickel monosilicide, and
a film thickness of the silicide film being below 20 nm including 20 nm.

2. A semiconductor device according to claim 1, further comprising:
another silicide film formed on the gate electrode,
said another silicide film being formed of nickel monosilicide,
a film thickness of said another silicide film being below 20 nm including 20 nm.

3. A semiconductor device comprising:
a gate electrode formed over a semiconductor substrate;
a source/drain diffused layer formed in the semiconductor substrate on both sides of the gate electrode;
an Si₁₋ₓGeₓ film which is buried in the source/drain diffused layer and whose composition ratio x is 0<x<1; and
a silicide film formed on the Si₁₋ₓGeₓ film,
the silicide film being formed of NiSi₁₋ₓGeₓ whose composition ratio x is 0<x<1, and
a film thickness of the silicide film being below 20 nm including 20 nm.

4. A semiconductor device according to claim 3, further comprising:
another Si₁₋ₓGeₓ film which is formed on the gate electrode and whose composition ratio x is 0<x<1, and
another silicide film formed on said another Si₁₋ₓGeₓ film,
said another silicide film being formed of NiSi₁₋ₓGeₓ whose composition ratio x is 0<x<1, and
a film thickness of said another silicide film being below 20 nm including 20 nm.

5. A semiconductor device comprising:
a gate electrode formed over a semiconductor substrate;
a source/drain diffused layer formed in the semiconductor substrate on both sides of the gate electrode,
an Si_{1-x-y}GeₓC_{y} film which is buried in the source/drain diffused layer and whose composition ratios x, y satisfy 0<x<1, 0<y<0.01 and 1−x−y>0; and
a silicide film formed on the Si_{1-x-y}GeₓC_{y} film,
the silicide film being formed of NiSi_{1-x-y}GeₓC_{y} whose composition ratios x, y satisfy 0<x<1, 0<y<0.01 and 1−x−y>0, and
a film thickness of the silicide film being below 20 nm including 20 nm.

6. A semiconductor device according to claim 5, further comprising:
another Si_{1-x-y}GeₓC_{y} film which is formed on the gate electrode and whose composition ratios x, y satisfy 0<x<1, 0<y<0.01 and 1−x−y>0, and
another silicide film formed on said another Si_{1-x-y}GeₓC_{y} film,
said another silicide film being formed of NiSi_{1-x-y}GeₓC_{y} whose composition ratios x, y satisfy 0<x<1, 0<y<0.01 and 1−x−y>0, and
a film thickness of said another silicide film being below 20 nm including 20 nm.

7. A method for fabricating a semiconductor device comprising the steps of:
forming a gate electrode over a semiconductor substrate;
forming a source/drain diffused layer in the semiconductor substrate on both sides of the gate electrode;
forming a nickel film on the source/drain diffused layer;
performing a first thermal processing to react a lower part of the nickel film and an upper part of the source/drain diffused layer with each other to form a nickel silicide film on the source/drain diffused layer;
etching off selectively a part of the nickel film, which has not reacted; and
performing a second thermal processing to further react the nickel silicide film and an upper part of the source/drain diffused layer with each other.

8. A method for fabricating a semiconductor device according to claim 7, wherein
in the step of forming the nickel film, the nickel film is formed further on the gate electrode,
in the step of performing a first thermal processing, a lower part of the nickel film and an upper part of the gate electrode are reacted with each other to form the nickel silicide film further on the gate electrode,
in the step of etching off selectively the part of the nickel film, which has not reacted, the part of the nickel film on the gate electrode, which has not reacted, is selectively etched off, and
in step of performing the second thermal processing, the nickel silicide film on the gate electrode and an upper part of the gate electrode is further reacted with each other.

9. A method for fabricating a semiconductor device comprising the steps of:
forming a gate electrode over a semiconductor substrate;
forming a source/drain diffused layer in the semiconductor substrate on both sides of the gate electrode;
burying Si₁₋ₓGeₓ film whose composition ratio x is 0<x<1 in the source/drain diffused layer;
forming a nickel film on the Si₁₋ₓGeₓ film;
performing a first thermal processing to react a lower part of the nickel film and an upper part of the Si₁₋ₓGeₓ film to form a nickel silicide film on the Si₁₋ₓGeₓ film;
etching off selectively a part of the nickel film, which has not reacted; and
performing a second thermal processing to further react the nickel silicide film and an upper part of the Si₁₋ₓGeₓ film with each other.

10. A method for fabricating a semiconductor device according to claim 9, further comprising before the step of forming the nickel film, the step of:
forming another Si₁₋ₓGeₓ film whose composition ratio x is 0<x<1 on the gate electrode,
in the step of forming the nickel film, the nickel film being formed further on said another Si₁₋ₓGeₓ film,
in the step of performing the first thermal processing, a lower part of the nickel film and an upper part of said another Si₁₋ₓGeₓ film being reacted with each other to further form the nickel silicide film on said another Si₁₋ₓGeₓ film,
in the step of etching off selectively the part of the nickel film, which has not reacted, a part of the nickel film on said another Si₁₋ₓGeₓ film, which has not reacted, being selectively etched off, and
in the step of performing the second thermal processing, the nickel silicide film on said another Si₁₋ₓGeₓ film and an upper part of the said another Si₁₋ₓGeₓ film being further reacted with each other.

11. A method for fabricating a semiconductor device comprising the steps of:
forming a gate electrode over a semiconductor substrate;
forming a source/drain diffused layer in the semiconductor substrate on both sides of the gate electrode;
burying an Si_{1-x-y}GeₓC_{y} film whose composition ratios x, y satisfy 0<x<1, 0<y<0.01 and 1−x−y>0 in the source/drain diffused layer;
forming a nickel film on the Si_{1-x-y}GeₓC_{y} film;
performing a first thermal processing to react a lower part of the nickel film and an upper part of the Si_{1-x-y}GeₓC_{y} film with each other to form a nickel silicide film on the Si_{1-x-y}GeₓC_{y} film;
etching off selectively a part of the nickel film, which has not reacted; and
performing a second thermal processing to further react the nickel silicide film and an upper part of the Si_{1-x-y}GeₓC_{y} film with each other.

12. A method for fabricating a semiconductor device according to claim 11, further comprising before the step of forming the nickel silicide film, the step of:
forming another Si_{1-x-y}GeₓC_{y} film whose composition ratios x, y satisfy 0<x<1.0, 0<y<0.01 and 1−x−y>0 on the gate electrode,
in the step of forming the nickel film, the nickel film being formed further on said another Si_{1-x-y}GeₓC_{y} film,
in the step of performing the first thermal processing, a lower part of the nickel film and an upper part of said another Si_{1-x-y}GeₓC_{y} film being reacted with each other to further form the nickel silicide film on said another Si_{1-x-y}GeₓC_{y} film,
in the step of etching off selectively the part of the nickel film, which has not reacted, a part of the nickel film on said another Si_{1-x-y}GeₓC_{y} film, which has not reacted, being selectively etched off, and
in the step of performing the second thermal processing, the nickel silicide film on said another Si_{1-x-y}GeₓC_{y} film and an upper part of said another Si_{1-x-y}GeₓC_{y}film being further reacted with each other.

13. A method for fabricating a semiconductor device according to claim 7, wherein
in the step of forming the nickel film, the nickel film is formed in a thickness of above 17 nm including 17 nm.

14. A method for fabricating a semiconductor device according to claim 7, wherein
a temperature of the second thermal processing is higher than a temperature of the first thermal processing.

15. A method for fabricating a semiconductor device according to claim 7, wherein
a temperature of the first thermal processing is 200-400° C., and
a temperature of the second thermal processing is 350-650° C.

16. A method for fabricating a semiconductor device according to claim 7, wherein
in the step of performing the second thermal processing, a thermal processing is performed by spike annealing of 450-650° C.

17. A method for fabricating a semiconductor device according to claim 7, wherein
in the step of forming the nickel film, the nickel film is formed by sputtering.

18. A method for fabricating a semiconductor device according to claim 7, further comprising, after the step of forming the nickel film and before the step of performing the first thermal processing, the step of:
amorphizing the nickel film.

19. A method for fabricating a semiconductor device according to claim 18, wherein
in the step of amorphizing the nickel film, nickel ions are implanted into the nickel film to amorphize the nickel film.

20. A method for fabricating a semiconductor device according to claim 19, wherein
in the step of amorphizing the nickel film, the nickel ions are implanted into the nickel film under conditions of a 5-500 keV acceleration voltage and a 1×10¹⁴-1×10¹⁵ cm⁻² dose.

21. A method for fabricating a semiconductor device according to claim 7, further comprising, after the step of forming the nickel film and before the step of performing the first thermal processing, the step of:
forming a protection film for preventing oxidation of the nickel film on the nickel film.

22. A method for fabricating a semiconductor device according to claim 7, wherein
the steps from the step of forming the nickel film to the step of performing the first thermal processing are performed continuously without an exposure to the atmospheric air.
